(19) United States
(12) Patent Application Publication
(10) Pub. No.: US 2025/0212393 A1
(43) Pub. Date: Jun. 26, 2025

(54) SEMICONDUCTOR MEMORY DEVICE AND METHOD OF FABRICATING THE SAME

(71) Applicant: SAMSUNG ELECTRONICS CO., LTD., Suwon-si (KR)

(72) Inventors: Taejin Park, Suwon-si (KR); Kiseok Lee, Suwon-si (KR); Inho Cha, Suwon-si (KR); Sung Soo Yim, Suwon-si (KR)

(21) Appl. No.: 18/769,047

(22) Filed: Jul. 10, 2024

(30) Foreign Application Priority Data
Dec. 20, 2023 (KR) 10-2023-0187247

(51) Int. Cl. H10B 12/00

(52) U.S. Cl. CPC H10B 12/482; H10B 12/315; H10B 12/488; H10B 12/50

(57) ABSTRACT

A semiconductor memory device comprises a bit line on a semiconductor substrate and extending in a first direction, a channel pattern on the bit line and including a horizontal part and a vertical part connected to an end of the horizontal part, a word line on the channel pattern and extending in a second direction that intersects the first direction, and a landing pad on the channel pattern. The landing pad includes a first part in contact with a portion of a sidewall of the vertical part included in the channel pattern and a second part in the first part. The vertical part extends in a third direction that intersects the first direction and the second direction.

### CROSS-REFERENCE TO RELATED APPLICATION

This U.S. nonprovisional application claims priority under 35 U.S.C § 119 to Korean Patent Application No. 10-2023-0187247 filed on Dec. 20, 2023, in the Korean Intellectual Property Office, the disclosure of which is hereby incorporated by reference in its entirety.

### BACKGROUND

With the trend of reduction in design rule of a semiconductor memory device, the fabrication technology is being improved to increase integration, operating speed, and yield of the semiconductor memory device. Accordingly, transistors with vertical channels have been suggested to increase their integration, resistance, current driving capability, and so forth.

### SUMMARY

In general, in some aspects, the present disclosure is directed to a semiconductor memory device having improved electrical properties and increased integration.

According to some aspects, the present disclosure is directed to a semiconductor memory device may comprise: a bit line on a semiconductor substrate, the bit line extending in a first direction; a channel pattern on the bit line, the channel pattern including a horizontal part and a vertical part connected to an end of the horizontal part; a word line on the channel pattern, the word line extending in a second direction that intersects the first direction; and a landing pad on the channel pattern. The landing pad may include: a first part in contact with a portion of a sidewall of the vertical part included in the channel pattern; and a second part in the first part. The vertical part may extend in a third direction that intersects the first direction and the second direction.

According to some aspects, the present disclosure is directed to a semiconductor memory device may comprise: a bit line on a semiconductor substrate, the bit line extending in a first direction; a channel pattern on the bit line, the channel pattern including a horizontal part, a first vertical part, and a second vertical part, the first and second vertical parts being connected to opposite ends of the horizontal part; a first word line and a second word line on the horizontal part and between the first and second vertical parts; and a plurality of landing pads on the first and second vertical parts. Each of the first and second word lines may include: a bottom part adjacent to the bit line; and a top part adjacent to the landing pads. A distance between the first and second word lines may be different at the bottom part and the top part.

According to some aspects, the present disclosure is directed to a semiconductor memory device may comprise: a peripheral circuit structure that includes a plurality of peripheral circuits on a semiconductor substrate and a lower dielectric layer that covers the peripheral circuits; a plurality of bit lines that extend in a first direction on the peripheral circuit structure; a plurality of word lines that extend in a second direction on the bit lines, the second direction intersecting the first direction; a plurality of channel patterns between the bit lines and the word lines; a gate dielectric layer between the word lines and the channel patterns; a plurality of data storage patterns on the channel patterns; and a plurality of landing pads between the channel patterns and the data storage patterns. Each of the channel patterns may include: a horizontal part; and a plurality of vertical parts that extend in a third direction from the horizontal part, the third direction intersecting the first and second directions. Each of the landing pads may include: a first part in contact with portions of sidewalls of the vertical parts; and a second part on the first part.

### BRIEF DESCRIPTION OF DRAWINGS

FIG. 1 illustrates a block diagram showing an example of a semiconductor memory device according to some implementations.

FIG. 2 illustrates a simplified perspective view showing an example of a semiconductor memory device according to some implementations.

FIG. 3A illustrates a plan view showing an example of a semiconductor memory device according to some implementations.

FIGS. 3B and 3C illustrate cross-sectional views taken along lines A-A′, B-B′, C-C′, and D-D′ of FIG. 3A, showing an example of a semiconductor memory device according to some implementations.

FIGS. 4A to 4H illustrate cross-sectional views of section P depicted in FIG. 3B, partially showing an example of a semiconductor memory device according to some implementations.

FIGS. 5A, 5B, and 5C illustrate cross-sectional views of section P depicted in FIG. 3B, partially showing an example of a semiconductor memory device according to some implementations.

FIG. 6A to 11C illustrate diagrams showing an example of a method of fabricating a semiconductor memory device according to some implementations.

FIG. 12A to 14C illustrate diagrams showing an example of a method of fabricating a semiconductor memory device according to some implementations.

### DETAILED DESCRIPTION

Example implementations will be more clearly understood from the following detailed description, taken in conjunction with the accompanying drawings.

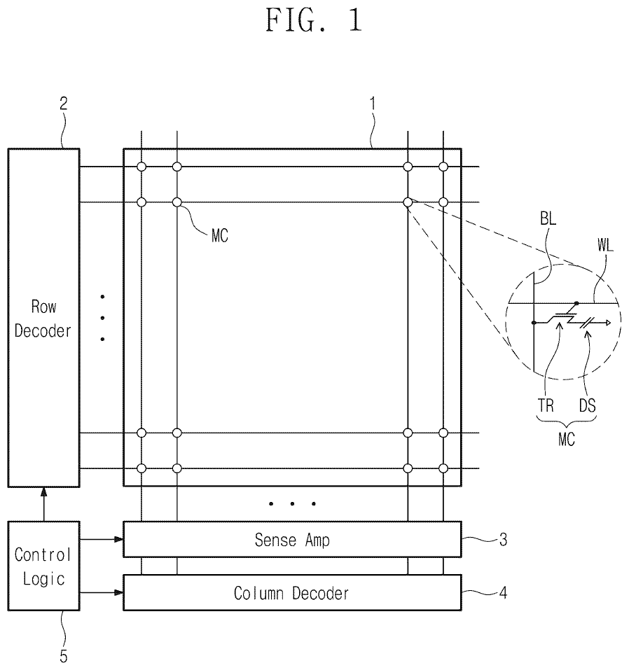

FIG. 1 illustrates a block diagram showing an example of a semiconductor memory device according to some implementations. In FIG. 1, a semiconductor memory device may include a memory cell array 1, a row decoder 2, a sense amplifier 3, a column decoder 4, and a control logic 5.

The memory cell array 1 may include a plurality of memory cells MC that are arranged two-dimensionally or three-dimensionally. Each of the memory cells MC may be connected between a word line WL and a bit line BL that cross each other.

Each of the memory cells MC may include a selection element TR and a data storage element DS, and the selection element TR and the data storage element DS may be electrically connected in series to each other. The selection element TR may be connected between the data storage element DS and the word line WL, and the data storage element DS may be connected through the selection element TR to the bit line BL. The selection element TR may be a field effect transistor (FET), and the data storage element DS may be a capacitor, a magnetic tunnel junction pattern, or a variable resistor. For example, the selection element TR may include a transistor, a gate electrode of the transistor may be connected to the word line WL, and source/drain terminals of the transistor may be connected to the bit line BL and the data storage element DS.

The row decoder 2 may decode an address that is externally input, and may select one of the word lines WL of the memory cell array 1. The address that is decoded in the row decoder 2 may be provided to a row driver, and in response to a control operation of control circuits, the row driver may provide a certain voltage to a selected word line WL and each of non-selected word lines WL.

In response to an address that is decoded from the column decoder 4, the sense amplifier 3 may detect and amplify a voltage difference between a selected bit line BL and a reference bit line, and may then output the amplified voltage difference.

The column decoder 4 may provide a data delivery pathway between the sense amplifier 3 and an external device (e.g., a memory controller). The column decoder 4 may decode an address that is externally input and may select one of the bit lines BL.

The control logic 5 may generate control signals that control operations to write data to the memory cell array 1 and/or to read data from the memory cell array 1.

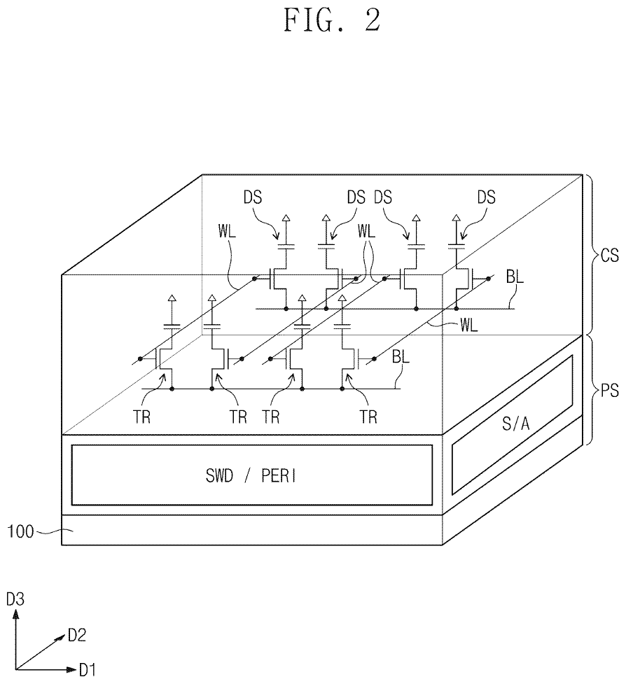

FIG. 2 illustrates a simplified perspective view showing an example of a semiconductor memory device according to some implementations. In FIG. 2, a semiconductor memory device may include a peripheral circuit structure PS on a semiconductor substrate 100, and a cell array structure CS on the peripheral circuit structure PS. For example, the peripheral circuit structure PS may be positioned between the semiconductor substrate 100 and the cell array structure CS in a third direction D3 perpendicular to a top surface of the semiconductor substrate 100.

The peripheral circuit structure PS may include a core/peripheral circuits that are formed on the semiconductor substrate 100. The core/peripheral circuits may include the row decoder, the column decoder, the sense amplifier, and the control logic of FIG. 1.

The cell array structure CS may include bit lines BL, word lines WL, and the memory cells MC of FIG. 1 between the bit lines BL and the word lines WL. The memory cells MC of FIG. 1 may be arranged two-dimensionally or three-dimensionally on a plane defined by a first direction D1 and a second direction D2. Each of the memory cells MC of FIG. 1 may include a selection element TR and a data storage element DS.

For example, the selection element TR may include a vertical channel transistor (VCT). A channel of the vertical channel transistor may have a shape that extends in a direction (e.g., the third direction D3) perpendicular to the top surface of the semiconductor substrate 100. The data storage element DS may be a capacitor.

The present disclosure, however, are not limited to that discussed above. The semiconductor memory device may include the cell array structure CS on the semiconductor substrate 100, and may also include the peripheral circuit structure PS on the cell array structure CS. For example, the cell array structure CS may be positioned between the semiconductor substrate 100 and the peripheral circuit structure PS.

The semiconductor memory device may have a chip-to-chip (C2C) structure. In this description, the C2C structure may refer to a structure in which an upper chip including the cell array structure CS is connected in a bonding manner to a lower chip including the peripheral circuit structure PS. For example, the upper chip and the lower chip may be connected in a hybrid bonding manner. The term “hybrid bonding” may denote that two components including the same material are merged at an interface therebetween.

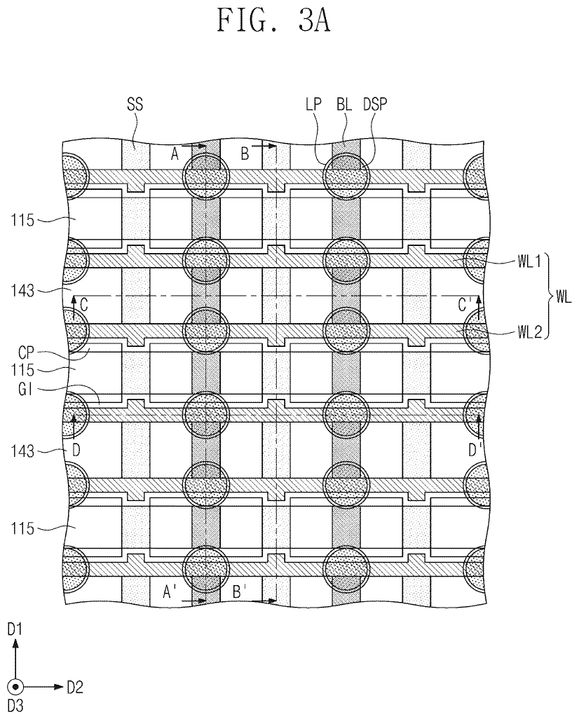

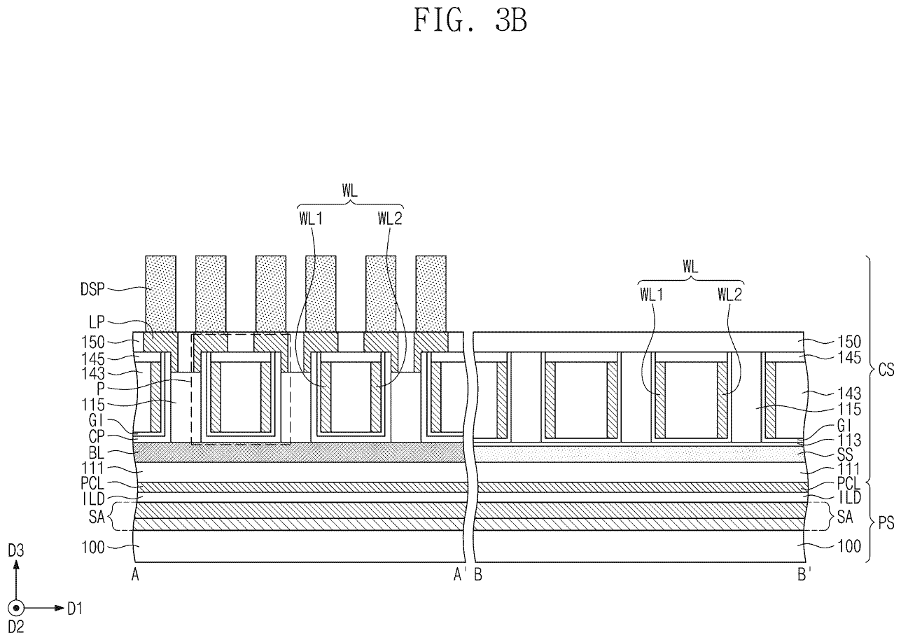

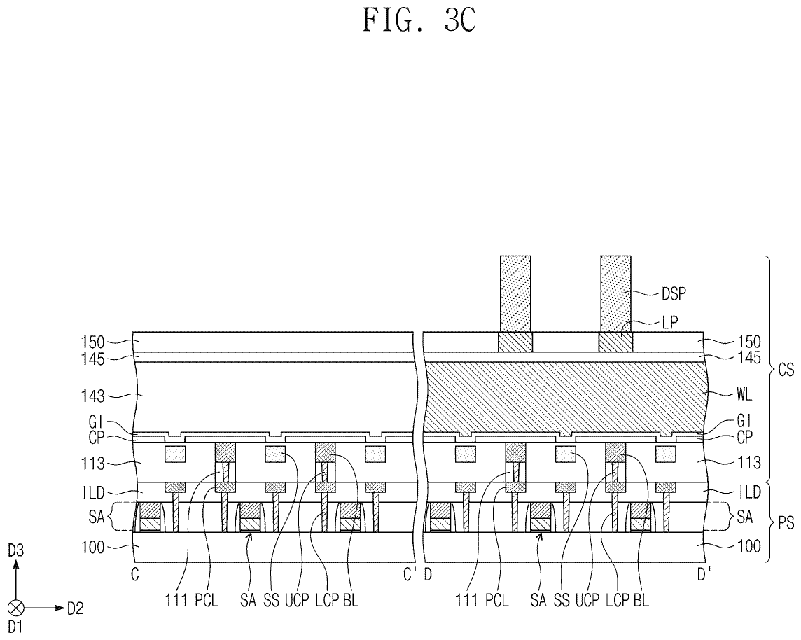

FIG. 3A illustrates a plan view showing an example of a semiconductor memory device according to some implementations. FIGS. 3B and 3C illustrate cross-sectional views taken along lines A-A′, B-B′, C-C′, and D-D′ of FIG. 3A, showing an example of a semiconductor memory device according to some implementations.

In FIGS. 3A, 3B, and 3C, a semiconductor memory device may include a peripheral circuit structure PS and a cell array structure CS on the peripheral circuit structure PS.

The peripheral circuit structure PS may include core circuits SA integrated on a semiconductor substrate 100, a lower dielectric layer ILD that covers the core circuits SA, lower contact plugs LCP, and circuit lines PCL.

The semiconductor substrate 100 may be a monocrystalline silicon substrate, but the present inventive concepts are not limited thereto. The semiconductor substrate 100 may have a top surface parallel to a first direction D1 and a second direction D2. The top surface of the semiconductor substrate 100 may be perpendicular to a third direction D3.

The core circuits SA may include NMOS and PMOS transistors integrated on the semiconductor substrate 100. The core circuits SA may be electrically connected through circuit lines PCL to bit lines BL and word lines WL.

On the semiconductor substrate 100, the lower dielectric layer ILD may cover the core circuits SA, the circuit lines PCL, and the lower contact plugs LCP. The lower contact plugs LCP may be electrically connected to the core circuits SA and the circuit lines PCL. The lower dielectric layer ILD may have a substantially flat top surface. The lower dielectric layer ILD may include, for example, one or more of silicon oxide, silicon nitride, silicon oxynitride, and low-k dielectric materials. In some implementations, the lower dielectric layer ILD may be formed of a multiple layer including different materials from each other.

The cell array structure CS may be positioned on the lower dielectric layer ILD. The cell array structure CS may include bit lines BL, channel patterns CP, first and second word lines WL1 and WL2, a gate dielectric layer GI, landing pads LP, and data storage patterns DSP.

On the lower dielectric layer ILD, the bit lines BL may extend in the first direction D1 and may be spaced apart from each other in the second direction D2.

For example, the bit lines BL may include doped polysilicon, metal, conductive metal nitride, conductive metal silicide, conductive metal oxide, or any combination thereof. The bit lines BL may be formed of a single or multiple layer. The bit lines BL may include a carbon-based two-dimensional material such as graphene, a carbon-based three-dimensional material such as carbon nano-tube, or any combination thereof.

A first interlayer dielectric pattern 111 may be provided on the lower dielectric layer ILD. The first interlayer dielectric pattern 111 may cover a portion of the lower dielectric layer ILD. The first interlayer dielectric pattern 111 may be positioned between the bit lines BL and the circuit lines PCL. The first interlayer dielectric pattern 111 may surround upper contact plugs UCP that connect the bit lines BL to the circuit lines PCL.

A second interlayer dielectric pattern 113 may be provided on the lower dielectric layer ILD. The second interlayer dielectric pattern 113 may cover the first interlayer dielectric pattern 111. A portion of the second interlayer dielectric pattern 113 may be positioned between the bit lines BL. For example, the first and second interlayer dielectric patterns 111 and 113 may include one or more of silicon oxide, silicon nitride, silicon oxynitride, and low-k dielectric materials.

Shield structures SS may be provided in the second interlayer dielectric pattern 113. Each of the shield structures SS may be positioned between neighboring bit lines BL. Each of the shield structures SS may extend in the first direction D1. The shield structures SS may be spaced apart from each other in the second direction D2. Top surfaces of the shield structures SS may be lower than top surfaces of the bit lines BL. For example, the shield structures SS may include a conductive material such as metal, and the conductive material may include therein an air gap or a void.

Mold dielectric patterns 115 may be provided on the second interlayer dielectric pattern 113 and the bit lines BL. Each of the mold dielectric patterns 115 may extend in the second direction D2, while running across the bit lines BL. For example, the mold dielectric patterns 115 may include one or more of silicon oxide, silicon nitride, silicon oxynitride, and low-k dielectric materials.

The channel patterns CP may be positioned on the bit lines BL. The channel patterns CP may be spaced apart from each other in the second direction D2 between the mold dielectric patterns 115. Each of the channel patterns CP may have a U-shaped cross-section. A width in the second direction D2 of each of the channel patterns CP may be greater than a width in the second direction D2 of each of the bit lines BL.

For example, the channel patterns CP may include an oxide semiconductor. The oxide semiconductor may include InₓGa_{y}Zn₂O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or any combination thereof. For example, the channel patterns CP may include indium-gallium-zinc oxide (IGZO). The channel patterns CP may each be formed of a single layer including one oxide semiconductor or a multiple layer including different oxide semiconductors. The channel patterns CP may include an amorphous, crystalline, or polycrystalline oxide semiconductor. The channel patterns CP may each have a bandgap energy greater than that of silicon. For example, the channel patterns CP may each have a bandgap energy of about 1.5 eV to about 5.6 eV, and may exhibit optimum channel performance when the bandgap energy is in a range of about 2.0 eV to about 4.0 eV.

The first and second word lines WL1 and WL2 may be positioned on the channel patterns CP. The first and second word lines WL1 and WL2 may extend in the second direction D2, while running across the bit lines BL and the channel patterns CP. The first and second word lines WL1 and WL2 may be alternately arranged along the first direction D1. For example, a pair of first and second word lines WL1 and WL2 may be positioned corresponding to the channel patterns CP.

The first and second word lines WL1 and WL2 may include, for example, doped polysilicon, metal, conductive metal nitride, conductive metal silicide, conductive metal oxide, or any combination thereof. The first and second word lines WL1 and WL2 may each be formed of a single layer or a multiple layer that includes different materials from each other. The first and second word lines WL1 and WL2 may include a carbon-based two-dimensional material such as graphene, a carbon-based three-dimensional material such as carbon nano-tube, or any combination thereof.

First dielectric patterns 143 may be provided between the first and second word lines WL1 and WL2. Each of the first dielectric patterns 143 may be positioned between a corresponding pair of first and second word lines WL1 and WL2. Each of the first dielectric patterns 143 may extend along the second direction D2. The first dielectric patterns 143 may be spaced apart from each other in the first direction D1. The first dielectric patterns 143 and the mold dielectric patterns 115 may be alternately arranged along the first direction D1.

Capping patterns 145 may be provided on the first and second word lines WL1 and WL2. The capping patterns 145 may cover top surfaces of the first dielectric patterns 143. Each of the capping patterns 145 may extend along the second direction D2. The capping patterns 145 may include a dielectric material different from that of the first dielectric patterns 143. For example, the first dielectric patterns 143 may include silicon oxide, and the capping patterns 145 may include silicon nitride.

The gate dielectric layer GI may be provided between the channel patterns CP and the first and second word lines WL1 and WL2 and between the channel patterns CP and the first dielectric patterns 143. The gate dielectric layer GI may be in contact with the first and second word lines WL1 and WL2 and with the channel patterns CP or the second interlayer dielectric pattern 113. The gate dielectric layer GI on the channel patterns CP may extend along inner sidewalls of the channel patterns CP.

The gate dielectric layer GI may include, for example, silicon oxide, silicon oxynitride, high-k dielectric materials whose dielectric constant is greater than that of silicon oxide, or any combination thereof. The high-k dielectric material may include HfO₂, HfSiO, HfSiON, HfTaO, HfTiO, HfZrO, ZrO₂, Al₂O₃, or any combination thereof, but the present inventive concepts are not limited thereto.

The landing pads LP may each be positioned on a corresponding one of the first and second word lines WL1 and WL2. The landing pads LP may be in contact with the channel patterns CP, the mold dielectric patterns 115, and the capping patterns 145. Each of the landing pads LP may have a circular shape when viewed in plan, but the present disclosure is not limited thereto. For example, each of the landing pads LP may have an oval shape, a rectangular shape, a square shape, a rhombic shape, a hexagonal shape, or any other suitable shapes when viewed in plan. The landing pads LP may be spaced apart from each other in the first direction D1 and the second direction D2. The landing pads LP may include, for example, doped polysilicon, metal, conductive metal nitride, conductive metal silicide, conductive metal oxide, or any combination thereof.

Second dielectric patterns 150 may be provided on the capping patterns 145 and the mold dielectric patterns 115. As each of the second dielectric patterns 150 is positioned between the landing pads LP, the second dielectric patterns 150 may electrically insulate the landing pads LP from each other. The second dielectric patterns 150 may have their top surfaces coplanar with those of the landing pads LP.

The data storage patterns DSP may be positioned on the landing pads LP. The data storage patterns DSP may be electrically connected through the landing pads LP to the channel patterns CP. When viewed in plan, each of the data storage patterns DSP may overlap a corresponding one of the landing pads LP. For example, the data storage patterns DSP may be spaced apart from each other in the first direction D1 and the second direction D2.

For example, the data storage patterns DSP may each be a capacitor. In some implementations, the data storage patterns DSP may include a bottom electrode, a top electrode, and a dielectric layer between the bottom electrode and the top electrode. The bottom electrode may be in contact with the landing pad LP. Alternatively, the data storage patterns DSP may each be a variable resistance pattern whose two resistance states can be switched due to an electrical pulse applied to a memory element. In some implementations, the data storage patterns DSP may include a phase-change material whose crystalline state is changed based on an amount of current, perovskite compounds, transition metal oxide, magnetic materials, ferromagnetic materials, or antiferromagnetic materials.

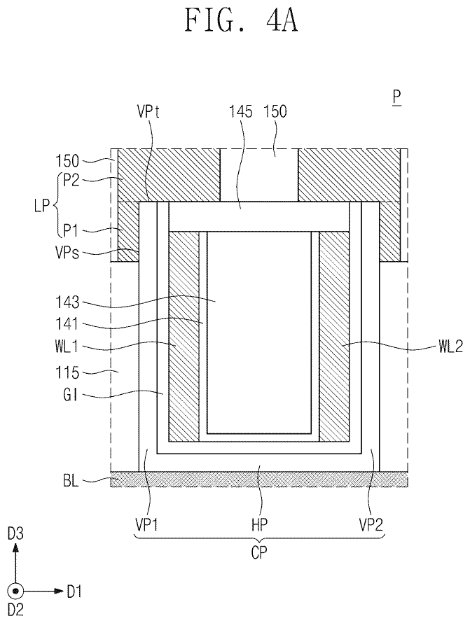

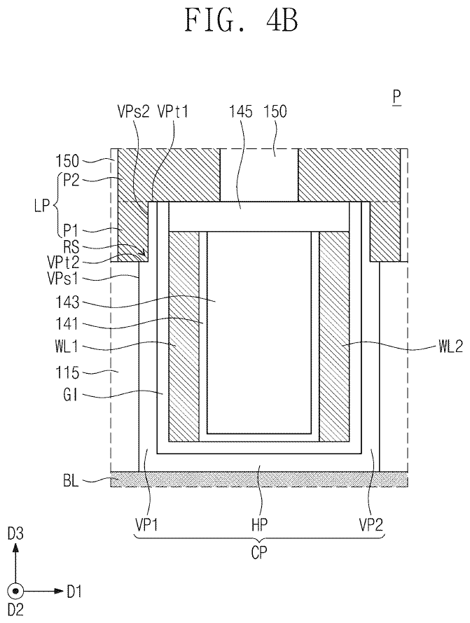

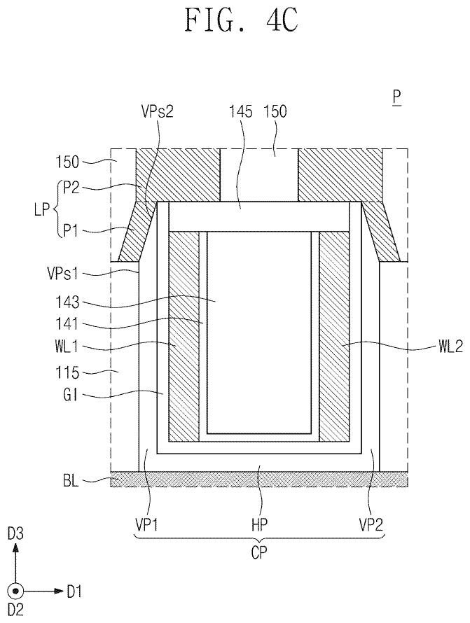

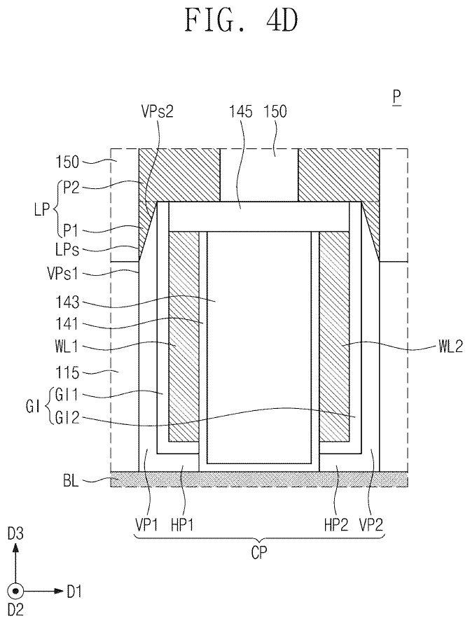

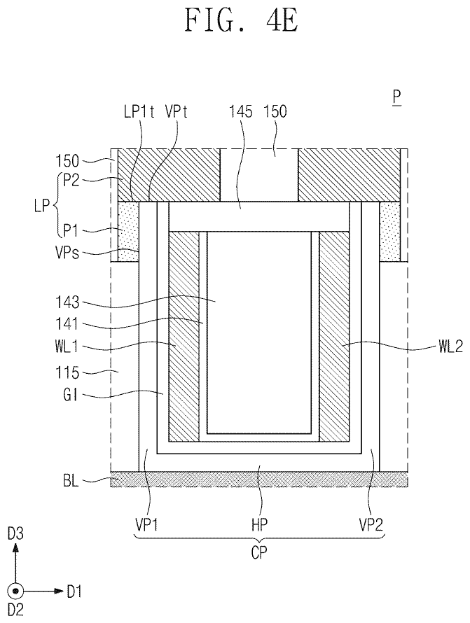

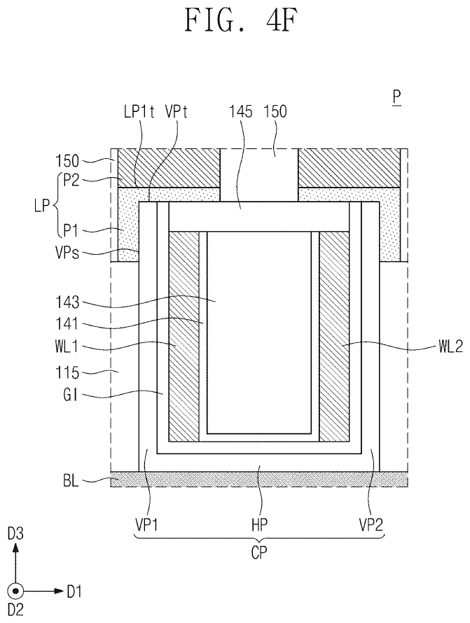

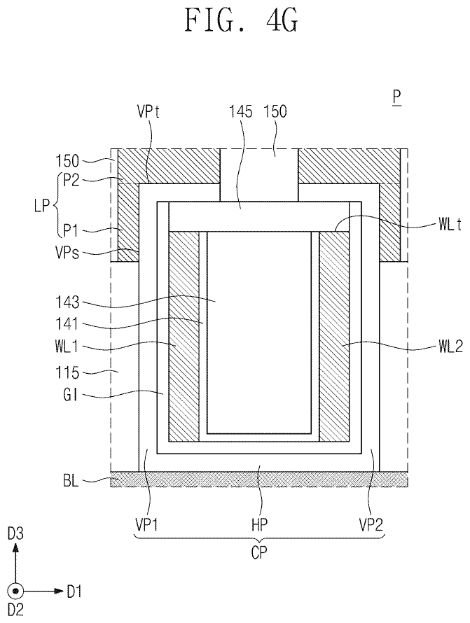

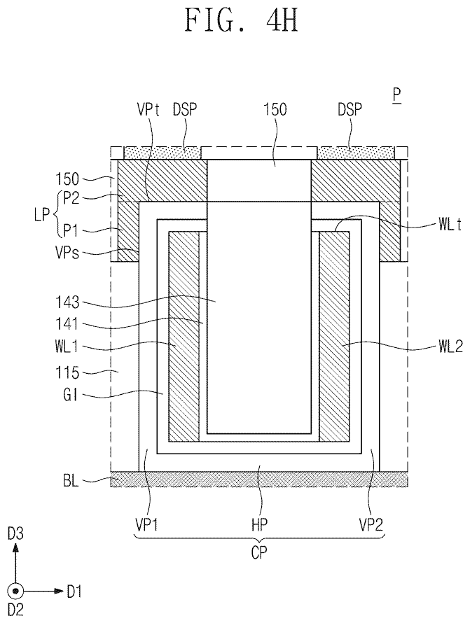

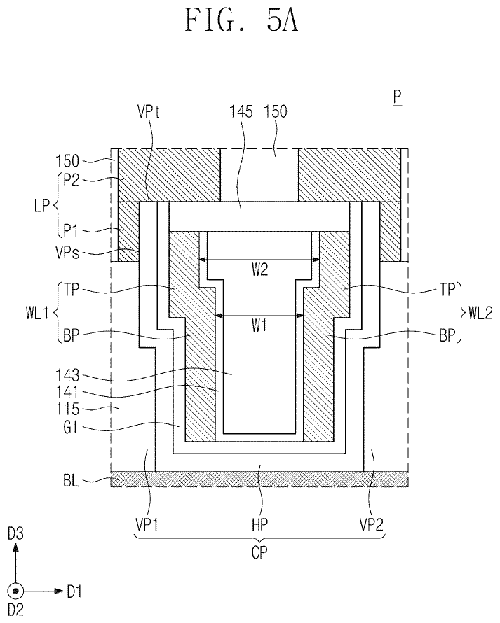

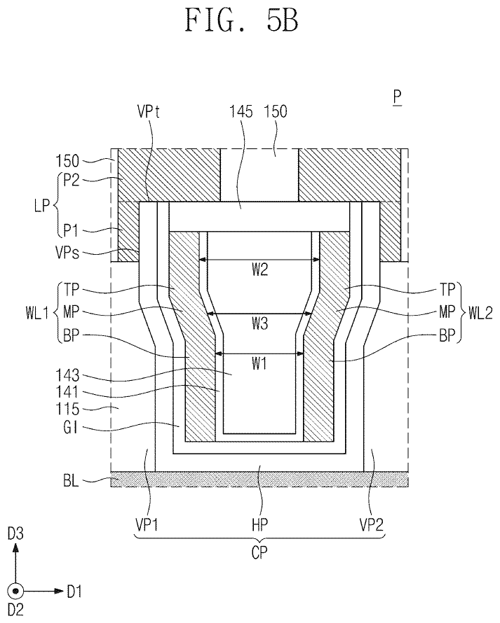

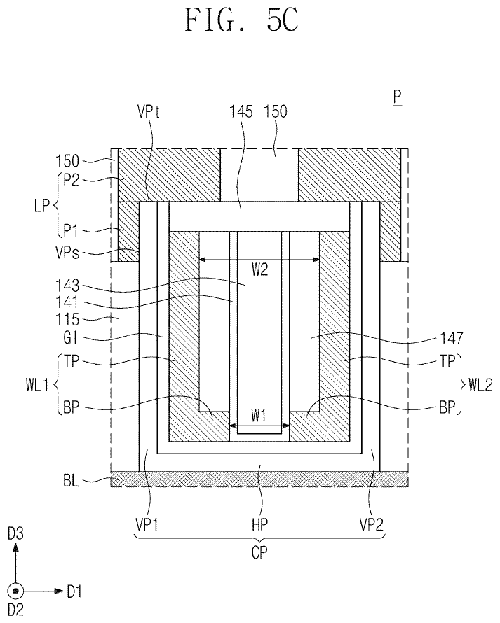

FIGS. 4A to 4H illustrate cross-sectional views of section P depicted in FIG. 3B, partially showing an example of a semiconductor memory device according to some implementations. In FIG. 4A, the channel pattern CP may include a horizontal part HP and a vertical part VP1 and VP2 connected to the horizontal part HP. The horizontal part HP may have a shape that extends in the first direction D1 on the bit line BL. The horizontal part HP may be in direct contact with the top surface of the bit line BL. The vertical part VP1 and VP2 may include a first vertical part VP1 and a second vertical part VP2. In some implementations, the vertical part VP1 and VP2 may correspond to one of the first vertical part VP1 and the second vertical part VP2.

The first vertical part VP1 and the second vertical part VP2 may have their shapes that extend in the third direction D3 from opposite ends of the horizontal part HP. The first vertical part VP1 and the second vertical part VP2 may be spaced apart from each other in the first direction D1. As the channel pattern CP may have a uniform thickness, a thickness in the third direction D3 of the horizontal part HP may be substantially the same as a thickness in the first direction D1 of each of the first and second vertical parts VP1 and VP2.

The first word line WL1 and the second word line WL2 may be positioned on the horizontal part HP of the channel pattern CP. The first word line WL1 may have a shape that adjoins the first vertical part VP1 and extends in the third direction D3. The second word line WL2 may have a shape that adjoins the second vertical part VP2 and extends in the third direction D3. For example, on the horizontal part HP, the first word line WL1 may extend along an inner sidewall of the first vertical part VP1 and the second word line WL2 may extend along an inner sidewall of the second vertical part VP2. The first and second word lines WL1 and WL2 may have substantially the same thickness in the first direction D1.

The gate dielectric layer GI may be positioned between the first and second word lines WL1 and WL2, and may have a uniform thickness. The gate dielectric layer GI may be in contact with the channel pattern CP and the first and second word lines WL1 and WL2. On the horizontal part HP of the channel pattern CP, the gate dielectric layer GI may extend between the first vertical part VP1 and the first word line WL1 and between the second vertical part VP2 and the second word line WL2. The gate dielectric layer GI may have a cross-section similar to that of the channel pattern CP.

A capping layer 141 may be provided between the first dielectric pattern 143 and the first and second word lines WL1 and WL2. The capping layer 141 may be in contact with inner sidewalls of the first and second word lines WL1 and WL2. The capping layer 141 may be in contact with a portion of the gate dielectric layer GI. For example, the capping layer 141 may include a dielectric material the same as that of the capping pattern 145 and different from that of the first dielectric pattern 143. The capping layer 141 may interrupt diffusion of a material included in the first dielectric pattern 143. Therefore, the first and second word lines WL1 and WL2 may be prevented from oxidation.

The capping pattern 145 may be positioned on the first and second word lines WL1 and WL2, the capping layer 141, and the first dielectric pattern 143. The capping pattern 145 may have a top surface coplanar with those of the first and second vertical parts VP1 and VP2.

The landing pads LP may be correspondingly positioned on the first and second word lines WL1 and WL2. Each of the landing pads LP may include a first part P1 and a second part P2 on the first part P1. The first part P1 may be positioned on a sidewall of the vertical part VP1 or VP2. The first part P1 may be in partial contact with the sidewall of the vertical part VP1 or VP2. The second part P2 may be positioned on the capping pattern 145 and the vertical part VP1 or VP2. The second part P2 may be in contact with the top surface of the capping pattern 145 and the top surface of the vertical part VP1 or VP2. The second part P2 may be in contact with and connected to the first part P1. The second part P2 and the first part P1 may include substantially the same material and may be formed simultaneously with each other. In this case, an invisible interface may be present between the first part P1 and the second part P2.

The first part P1 may be horizontally separated from the first and second word lines WL1 and WL2 by the gate dielectric layer GI and the vertical part VP1 or VP2 of the channel pattern CP. The second part P2 may be vertically separated from the first and second word lines WL1 and WL2 by the capping pattern 145. For example, the landing pads LP may be separated from the first and second word lines WL1 and WL2.

In FIG. 4B, the vertical part VP1 or VP2 of the channel pattern CP may have a recess RS on a top end thereof. The recess RS may be a space formed by partially removing a top end of the vertical part VP1 or VP2. Thus, the top end of the vertical part VP1 or VP2 may have a width less than that of a lower portion of the vertical part VP1 or VP2.

The vertical part VP1 or VP2 may have a first top surface VPt1 and a second top surface VPt2 that are located at different levels. The vertical part VP1 or VP2 may have a first sidewall VPs1 and a second sidewall VPs2. The second sidewall VPs2 may be positioned between the first top surface VPt1 and the second top surface VPt2. The first sidewall VPs1 may correspond to an outer sidewall of the vertical part VP1 or VP2. For example, the first top surface VPt1 of the vertical part VP1 or VP2 may be adjacent to the inner sidewall of the vertical part VP1 or VP2. The second top surface VPt2 of the vertical part VP1 or VP2 may be adjacent to the outer sidewall of the vertical part VP1 or VP2. The first top surface VPt1 may be higher than the second top surface VPt2.

The first and second top surfaces VPt1 and VPt2 of the vertical part VP1 or VP2 may be parallel to the first and second direction D1 and D2. The first and second sidewalls VPs1 and VPs2 of the vertical part VP1 or VP2 may be parallel to the third direction D3. The present disclosure, however, are not limited thereto. For example, the first and second top surfaces VPt1 and VPt2 of the vertical part VP1 or VP2 may be curved surfaces or inclined surfaces, and likewise, the first and second sidewalls VPs1 and VPs2 of the vertical part VP1 or VP2 may be curved surfaces or inclined surfaces. Thus, the recess RS may have various cross-sections.

Each of the landing pads LP may be positioned on the channel pattern CP, and may include a first part P1 and a second part P2. The first part P1 may be positioned in the recess RS of the vertical part VP1 or VP2. The first part P1 may be in contact with the vertical part VP1 or VP2, while filling the recess RS. For example, the first part P1 may be in contact with the second sidewall VPs2 and the second top surface VPt2 of the vertical part VP1 or VP2. A bottom surface of the first part P1 may be coplanar with the second top surface VPt2 of the vertical part VP1 or VP2.

The second part P2 may be positioned on the first part P1 and in contact with the vertical part VP1 or VP2, the gate dielectric layer GI, and the capping pattern 145. A bottom surface of the second part P2 may be coplanar with the first top surface VPt1 of the vertical part VP1 or VP2.

In FIG. 4C, the vertical part VP1 or VP2 of the channel pattern CP may have a first sidewall VPs1 and a second sidewall VPs2 having different slopes from each other. The first sidewall VPs1 may be parallel to the third direction D3. The second sidewall VPs2 may not be parallel to the third direction D3. The second sidewall VPs2 may be parallel to a direction that intersects the third direction D3. For example, the second sidewall VPs2 may be a sidewall inclined to the third direction D3.

The second sidewall VPs2 may be positioned between the first sidewall VPs1 and the inner sidewall of the vertical part VP1 or VP2. For example, the vertical part VP1 or VP2 of the channel pattern CP may have a width that decreases with decreasing distance from the landing pad LP. In addition, the vertical part VP1 or VP2 of the channel pattern CP may have no top surface.

Each of the landing pads LP may be positioned on the channel pattern CP, and may include a first part P1 and a second part P2. The first part P1 may be positioned on and in contact with the second sidewall VPs2 of the vertical part VP1 or VP2. The first part P1 may have a constant width in the first direction D1. For example, the first part P1 may extend in a direction inclined relative to the third direction D3. The first part P1 may be spaced apart from the first sidewall VPs1 of the vertical part VP1 or VP2, but the present inventive concepts are not limited thereto.

The second part P2 may be positioned on the first part P1 and in contact with the capping pattern 145 and the gate dielectric layer GI. As the vertical part VP1 or VP2 of the channel pattern CP has no top surface, the second part P2 may be spaced apart from the vertical part VP1 or VP2 of the channel pattern CP.

In FIG. 4D, the channel pattern CP may include first and second horizontal parts HP1 and HP2 and first and second vertical parts VP1 and VP2. The first horizontal part HP1 and the second horizontal part HP2 may be spaced apart from each other in the first direction D1 on the bit line BL. The first vertical part VP1 may extend in the third direction D3 from an end of the first horizontal part HP1, and may be positioned adjacent to the first word line WL1. The second vertical part VP2 may extend in the third direction D3 from an end of the second horizontal part HP2, and may be positioned adjacent to the second word line WL2. For example, the first word line WL1 and the second word line WL2 may be positioned between the first vertical part VP1 and the second vertical part VP2.

Likewise, as shown in FIG. 4C, each of the first and second vertical parts VP1 and VP2 may have a first sidewall VPs1 and a second sidewall VPs2 having different slopes from each other. For example, neither the first vertical part VP1 nor the second vertical part VP2 may have a top surface. Each of the first and second vertical parts VP1 and VP2 may have a width in the first direction D1 that decreases with decreasing distance from the landing pad LP.

The gate dielectric layer GI may include a first gate dielectric layer GI1 and a second gate dielectric layer GI2 that are spaced apart from each other in the first direction D1. The first gate dielectric layer GI1 may be positioned on a top surface of the first horizontal part HP1 and an inner sidewall of the first vertical part VP1. The first gate dielectric layer GI1 may be positioned between the first word line WL1 and the first horizontal part HP1 and between the first word line WL1 and the first vertical part VP1. The first gate dielectric layer GI1 may be aligned with a sidewall of the first horizontal part HP1 spaced apart from the first vertical part VP1. The second gate dielectric layer GI2 may be positioned on a top surface of the second horizontal part HP2 and an inner sidewall of the second vertical part VP2. The second gate dielectric layer GI2 may be positioned between the second word line WL2 and the second horizontal part HP2 and between the second word line WL2 and the second vertical part VP2. The second gate dielectric layer GI2 may be aligned with a sidewall of the second horizontal part HP2 spaced apart from the second vertical part VP2.

The capping layer 141 may be positioned between the first horizontal part HP1 and the second horizontal part HP2, between the first gate dielectric layer GI1 and the second gate dielectric layer GI2, and between the first word line WL1 and the second word line WL2. In addition, the capping layer 141 may be in partial contact with the top surface of the bit line BL.

Each of the landing pads LP may be positioned on the channel pattern CP, and may include a first part P1 and a second part P2. The first part P1 may be positioned on and in contact with the second sidewall VPs2 of the vertical part VP1 or VP2. A width in the first direction D1 of the first part P1 may increase with increasing distance from the bit line BL. For example, the first part P1 may have a width that increases in the third direction D3. The second part P2 may be positioned on the first part P1, and the first part P1 and the second part P2 may have their outer sidewalls that are aligned with each other. In addition, the landing pads LP may have their outer sidewalls LPs each of which is aligned with the first sidewall VPs1 of the vertical part VP1 or VP2.

In FIG. 4E, each of the landing pads LP may be positioned on the channel pattern CP, and may include a first part P1 and a second part P2. The first part P1 may be positioned on a sidewall VPs of the vertical part VP1 or VP2 of the channel pattern CP, and the second part P2 may be positioned on the first part P1 and a top surface VPt of the vertical part VP1 or VP2 of the channel pattern CP. In addition, the first part P1 may be in partial contact with the sidewall VPs of the vertical part VP1 or VP2, and the second part P2 may be in contact with the top surface VPt of the vertical part VP1 or VP2. The present disclosure, however, are not limited thereto. For example, the first part P1 may have a shape substantially the same as that discussed with reference to FIGS. 4C and 4D.

The first part P1 and the second part P2 may include different materials from each other. In addition, the first part P1 and the second part P2 may be formed by different processes from each other. In some implementations, a visible interface may be present between the first part P1 and the second part P2. For example, the first part P1 may include one or more of conductive metal nitride (e.g., TiN, TaN, WN, NbN, TiAl, and TiAlN), conductive metal silicide (e.g., TiSi, TiSiN, TaSi, TaSiN, RuTiN, NiSi, and CoSi), and conductive metal oxide (e.g., IrOₓ and RuOₓ). The second part P2 may include metal, such as Al, Cu, Ti, Ta, Ru, W, Mo, Pt, Ni, and Co. When the channel pattern CP includes an oxide semiconductor, a contact resistance between the first part P1 and the channel pattern CP may be less than that between the second part P2 and the channel pattern CP. There may thus be a reduction in contact resistance between the channel pattern CP and the landing pads LP.

In FIG. 4F, each of the landing pads LP may be positioned on the channel pattern CP, and may include a first part P1 and a second part P2. The first part P1 and the second part P2 may include different materials from each other as discussed in FIG. 4E. For example, a visible interface may be present between the first part P1 and the second part P2, and a contact resistance between the first part P1 and the channel pattern CP may be less than that between the second part P2 and the channel pattern CP.

The first part P1 may extend onto the top surface VPt of the vertical part VP1 or VP2 of the channel pattern CP and onto the top surface of the capping pattern 145. The first part P1 may be in contact with a portion of the sidewall VPs of the vertical part VP1 or VP2 and with the top surface VPt of the vertical part VP1 or VP2. A top surface of the first part P1 may be higher than the top surface VPt of the vertical part VP1 or VP2. As the second part P2 is positioned on the first part P1, the second part P2 may be spaced apart in the third direction D3 from the vertical part VP1 or VP2. For example, the second part P2 may not be in contact with the vertical part VP1 or VP2. In such a configuration, as only the first part P1 is in contact with the channel pattern CP and the second part P2 is spaced apart from the channel pattern CP, there may be a reduction in contact resistance between the landing pads LP and the channel pattern CP.

In FIG. 4G, the channel pattern CP may include a horizontal part HP and first and second vertical parts VP1 and VP2 that extend in the third direction D3 from the horizontal part HP. The first and second vertical parts VP1 and VP2 may extend onto top surfaces WLt of the first and second word lines WL1 and WL2. For example, the first vertical part VP1 may extend from an outer sidewall of the first word line WL1 onto the top surface WLt of the first word line WL1. The second vertical part VP2 may extend from an outer sidewall of the second word line WL2 onto the top surface WLt of the second word line WL2. Accordingly, the first and second vertical parts VP1 and VP2 may cover a portion of the top surface of the capping pattern 145, and may be higher than the top surface of the capping pattern 145. In addition, the top surface VPt of the vertical part VP1 or VP2 may have an increased planar area.

Each of the landing pads LP may be positioned on the channel pattern CP, and may include a first part P1 and a second part P2. The first part P1 may be positioned on and in partial contact with the sidewall VPs of the vertical part VP1 or VP2. The second part P2 may be positioned on and in contact with the top surface VPt of the vertical part VP1 or VP2. For example, as an increased contact area is provided between the second part P2 and the vertical part VP1 or VP2, a reduced contact resistance may be provided between the channel pattern CP and the landing pads LP. As a portion of the vertical part VP1 or VP2 is positioned between the second part P2 and the capping pattern 145, the second part P2 may be spaced apart from the capping pattern 145 and the gate dielectric layer GI.

In FIG. 4H, the channel pattern CP may include a horizontal part HP and first and second vertical parts VP1 and VP2. The first and second vertical parts VP1 and VP2 may extend onto the top surfaces WLt of the first and second word lines WL1 and WL2. For example, the first and second vertical parts VP1 and VP2 may have substantially the same shape as discussed with reference to FIG. 4G.

The gate dielectric layer GI may be positioned between the channel pattern CP and the first word line WL1 and between the channel pattern CP and the second word line WL2. On the horizontal part HP of the channel pattern CP, the gate dielectric layer GI may extend between the first vertical part VP1 and the first word line WL1 and between the second vertical part VP2 and the second word line WL2. A portion of the gate dielectric layer GI may be in contact with the top surfaces WLt of the first and second word lines WL1 and WL2. For example, the gate dielectric layer GI may be in contact with three surfaces of each of the first and second word lines WL1 and WL2. Accordingly, the semiconductor memory device may improve in gate controllability.

In FIGS. 4A to 4H, the semiconductor memory device may include the landing pads LP that are positioned on the channel pattern CP and are in contact with portions of the sidewalls VPs of the vertical parts VP1 and VP2 and with the top surfaces VPt of the vertical parts VP1 and VP2. In some implementations, the semiconductor memory device may include the landing pads LP in contact with the inclined second sidewalls VPs2 of the vertical parts VP1 and VP2 of the channel pattern CP. Accordingly, an increased area may be provided between the channel pattern CP and the landing pads LP. As a reduced contact resistance is provided between the channel pattern CP and the landing pads LP, the semiconductor memory device may improve in electrical properties.

In some implementations, the semiconductor memory device may include the landing pads LP each of which includes the first part P1 on the sidewall VPs of the vertical part VP1 or VP2 of the channel pattern CP and the second part P2 on the first part P1. The first part P1 and the second part P2 may include different materials from each other. For example, a contact resistance between the first part P1 and the channel pattern CP may be less than that between the second part P2 and the channel pattern CP. There may thus be a reduction in contact resistance between the channel pattern CP and the landing pads LP. Accordingly, the semiconductor memory device may improve in electrical properties.

FIGS. 5A, 5B, and 5C illustrate cross-sectional views of section P depicted in FIG. 3B, partially showing an example of a semiconductor memory device according to some implementations. In FIG. 5A, each of the first word line WL1 and the second word line WL2 may include a bottom part BP and a top part TP. The bottom part BP may be positioned below the top part TP and adjacent to the bit line BL. The top part TP may be positioned on the bottom part BP and adjacent to the landing pads LP. Each of the bottom part BP and the top part TP may have a shape that extends in the third direction D3. The bottom part BP and the top part TP may be connected to each other.

The bottom part BP and the top part TP may be shifted from each other in the first direction D1, while having the same thickness in the first direction D1. The bottom part BP and the top part TP may have their sidewalls that are not aligned with each other. A portion of the bottom part BP may vertically overlap a portion of the top part TP. For example, the first and second word lines WL1 and WL2 may have their step difference on sidewalls thereof.

A distance between the bottom parts BP of the first and second word lines WL1 and WL2 may be different from that between the top parts TP of the first and second word lines WL1 and WL2. For example, a distance between the first and second word lines WL1 and WL2 may be different at the top part TP and the bottom part BP. A first distance W1 may refer to the distance between the bottom parts BP of the first and second word lines WL1 and WL2. A second distance W2 may refer to the distance between the top parts TP of the first and second word lines WL1 and WL2. The first distance W1 may be less than the second distance W2. The present inventive concepts, however, are not limited thereto, and the first distance W1 may be greater than the second distance W2.

The capping layer 141 may be positioned on the inner sidewalls of the first and second word lines WL1 and WL2. The gate dielectric layer GI and the vertical parts VP1 and VP2 of the channel pattern CP may be positioned on outer sidewalls of the first and second word lines WL1 and WL2. Each of the capping layer 141, the gate dielectric layer GI, and the vertical parts VP1 and VP2 of the channel pattern CP may have a uniform thickness, and may be positioned adjacent to the first and second word lines WL1 and WL2. For example, likewise the first and second word lines WL1 and WL2, the capping layer 141, the gate dielectric layer GI, and the vertical parts VP1 and VP2 of the channel pattern CP may have their sidewalls each of which has a step difference thereon.

In FIG. 5B, each of the first and second word lines WL1 and WL2 may further include a middle part MP between the top part TP and the bottom part BP. The middle part MP may connect the bottom part BP and the top part TP to each other. The middle part MP may be shifted in the first direction D1 from the top part TP and the bottom part BP. The middle part MP may have a substantially the same horizontal thickness as that of the top part TP and the bottom part BP. For example, the top part TP and the bottom part BP may each have a shape that extends in the third direction D3. The middle part MP may extend in a direction inclined relative to the third direction D3. For example, the top part TP and the bottom part BP may have sidewalls parallel to the third direction D3, and the middle part MP may have a sidewall inclined to the third direction D3. In addition, the sidewalls of the top, bottom, and middle parts TP, BP, and MP may not be aligned with each other.

A distance between the middle parts MP of the first and second word lines WL1 and WL2 may be different from that between the top parts TP of the first and second word lines WL1 and WL2 and that between the bottom parts BP of the first and second word lines WL1 and WL2. For example, a third distance W3 may refer to the distance between the middle parts MP of the first and second word lines WL1 and WL2. The third distance W3 may be greater than the first distance W1 and less than the second distance W2.

In FIG. 5C, each of the first and second word lines WL1 and WL2 may include a bottom part BP and a top part TP on the bottom part BP. The bottom part BP may extend in the first direction D1 on the horizontal part HP of the channel pattern CP. The top part TP may extend in the third direction D3 on the bottom part BP. The top part TP may be positioned adjacent to the vertical part VP1 or VP2 of the channel pattern CP. An outer sidewall of the top part TP may be aligned with one sidewall of the bottom part BP. The first and second word lines WL1 and WL2 may each have an L-shaped cross-section, and may be disposed mirror-symmetrically with each other in the first direction D1.

A distance between the first and second word lines WL1 and WL2 may be different at the top part TP and the bottom part BP. A first distance W1 may refer to a distance between the bottom parts BP of the first and second word lines WL1 and WL2. A second distance W2 may refer to a distance between the top parts TP of the first and second word lines WL1 and WL2. The first distance W1 may be less than the second distance W2.

A word-line spacer 147 may be provided on a top surface of the bottom part BP and an inner sidewall of the top part TP. The word-line spacer 147 may be positioned between the top part TP and the capping layer 141 and between the bottom part BP and the capping pattern 145. The word-line spacer 147 may be aligned with one sidewall of the bottom part BP. The word-line spacer 147 may prevent the first and second word lines WL1 and WL2 from being exposed in an etching process. For example, the word-line spacer 147 may include a dielectric material different from those of the capping layer 141 and the first dielectric pattern 143, but the present disclosure is not limited thereto.

In FIGS. 5A, 5B, and 5C, a distance between the first and second word lines WL1 and WL2 may be different at the top part TP and the bottom part BP. In addition, the first and second word lines WL1 and WL2 may have their sidewalls each of which has a step difference. Accordingly, there may be an increase in length of the channel pattern CP for the first and second word lines WL1 and WL2. For example, an increased channel length may be given to the memory cells MC of FIGS. 1 and 2. Accordingly, the semiconductor memory device may improve in electrical properties.

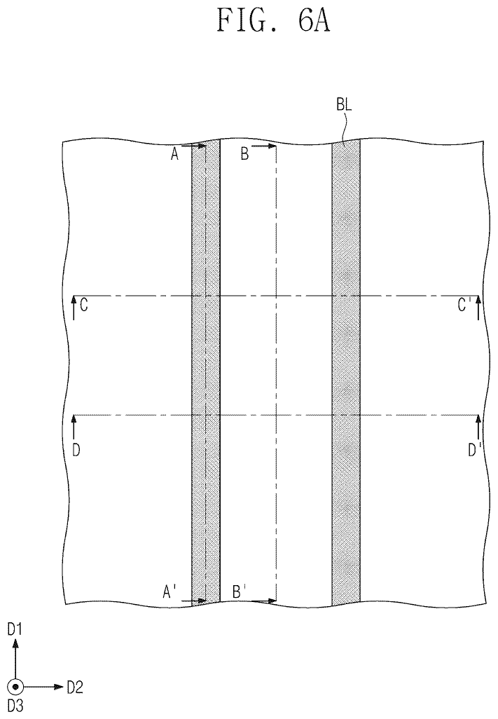

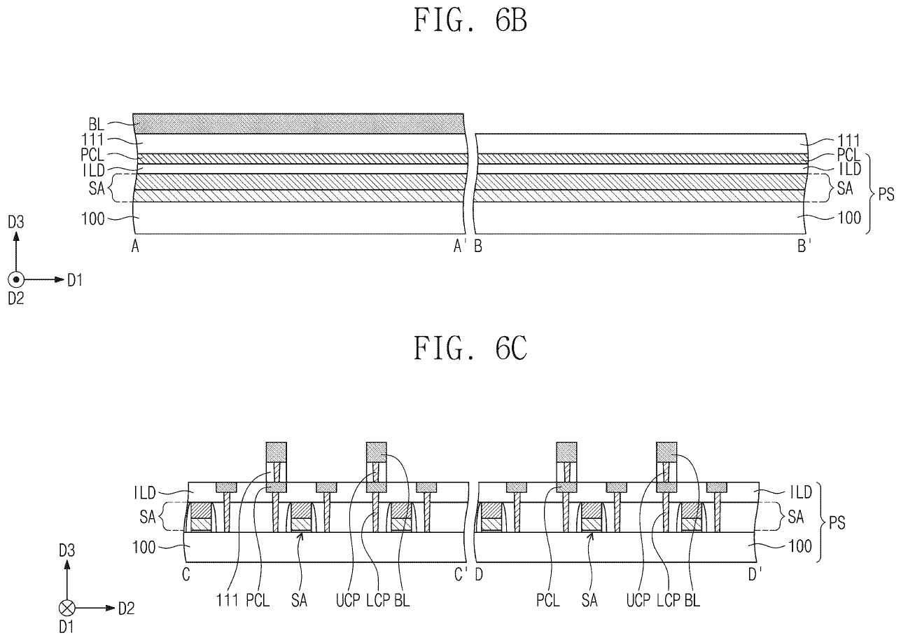

FIGS. 6A to 11C illustrate diagrams showing an example of a method of fabricating a semiconductor memory device according to some implementations. FIGS. 6A, 7A, 8A, 9A, 10A, and 11A illustrate plan views showing an example of a semiconductor memory device according to some implementations. FIGS. 6B, 6C, 7B, 7C, 8B, 8C, 9B, 9C, 10B, 10C, 11B, and 11C illustrate cross-sectional views taken along lines A-A′, B-B′, C-C′, and D-D′ of FIGS. 6A, 7A, 9A, 10A, and 11A according to some implementations.

In FIGS. 6A, 6B, and 6C, a peripheral circuit structure PS including core circuits SA may be formed on a semiconductor substrate 100. For example, the core circuits SA may be formed on the semiconductor substrate 100, and a lower dielectric layer ILD may be formed to cover the core circuits SA. The lower dielectric layer ILD may include one or more of silicon oxide, silicon nitride, silicon oxynitride, and low-k dielectric materials, and may be formed of a single or multiple layers including different materials from each other.

Circuit lines PCL may be formed in the lower dielectric layer ILD, and lower contact plugs LCP may be formed to connect with the circuit lines PCL. The circuit lines PCL may be electrically connected through the lower contact plugs LCP to the core circuits SA.

Bit lines BL may be formed on the lower dielectric layer ILD. The formation of the bit lines BL may include forming a first interlayer dielectric layer on the lower dielectric layer ILD, forming the lower contact plugs LCP to penetrate the first interlayer dielectric layer, depositing a lower conductive layer on the first interlayer dielectric layer, and patterning the lower conductive layer and the first interlayer dielectric layer. Accordingly, the lower conductive layer and the first interlayer dielectric layer may be formed into the bit lines BL and a first interlayer dielectric pattern 111. In addition, a portion of the lower dielectric layer ILD may be exposed.

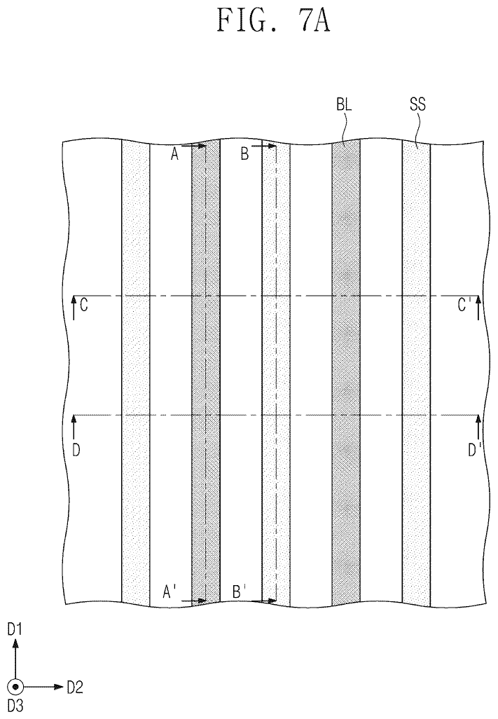

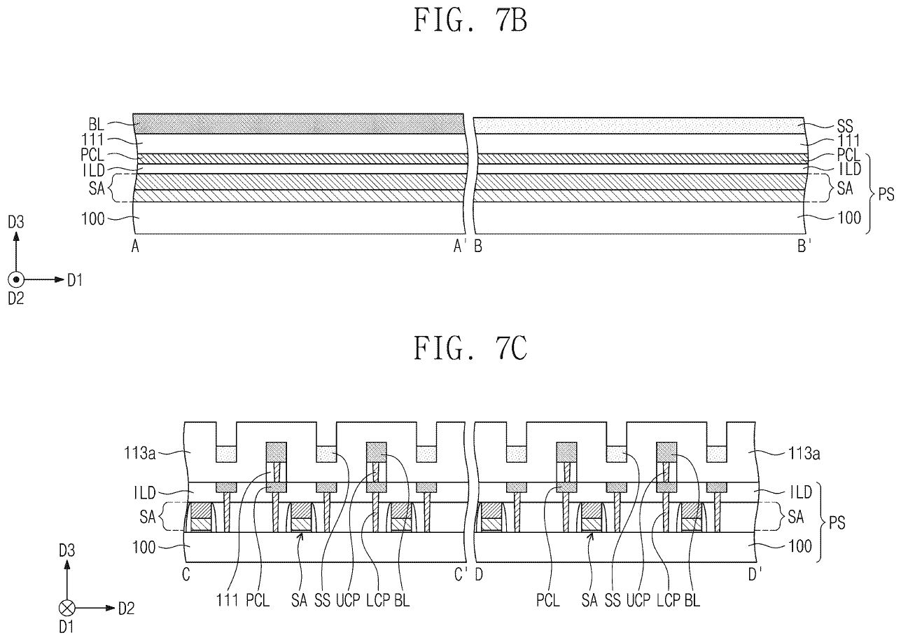

In FIGS. 7A, 7B, and 7C, a second interlayer dielectric layer 113a may be formed on the lower dielectric layer ILD. The second interlayer dielectric layer 113a may have a uniform thickness that covers the bit lines BL and a top surface of the lower dielectric layer ILD. The thickness of the second interlayer dielectric layer 113a may be less than half an interval between neighboring bit lines BL. Accordingly, the second interlayer dielectric layer 113a may define gaps positioned between neighboring bit lines BL. Each of the gaps may extend in a first direction D1 parallel to the bit lines BL.

Afterwards, shield structures SS may be formed to fill the gaps of the second interlayer dielectric layer 113a. Each of the shield structures SS may be positioned between neighboring bit lines BL. The formation of the shield structures SS may include forming on the second interlayer dielectric layer 113a a shield layer that fills the gaps and recessing a top surface of the shield layer. For example, the shield structures SS may include a metallic material such as W, Ti, Ni, and Co or a conductive two-dimensional (2D) material such as graphene.

The formation of the shield structures SS may be omitted. In some implementations, the second interlayer dielectric layer 113a may fill a space between neighboring bit lines BL. The present disclosure, however, is not limited thereto.

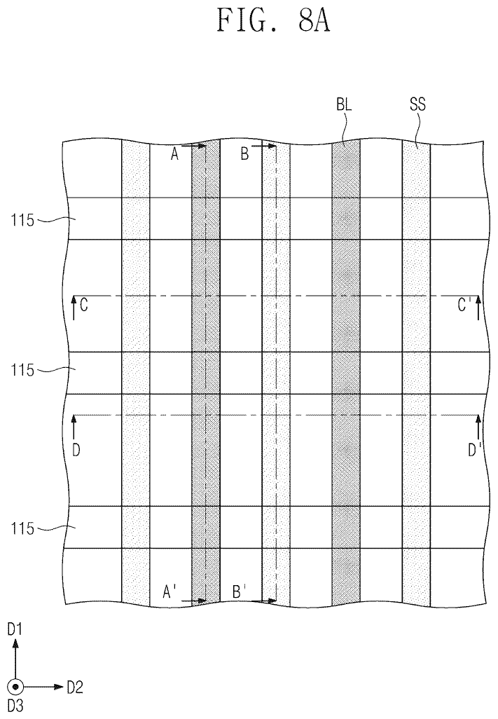

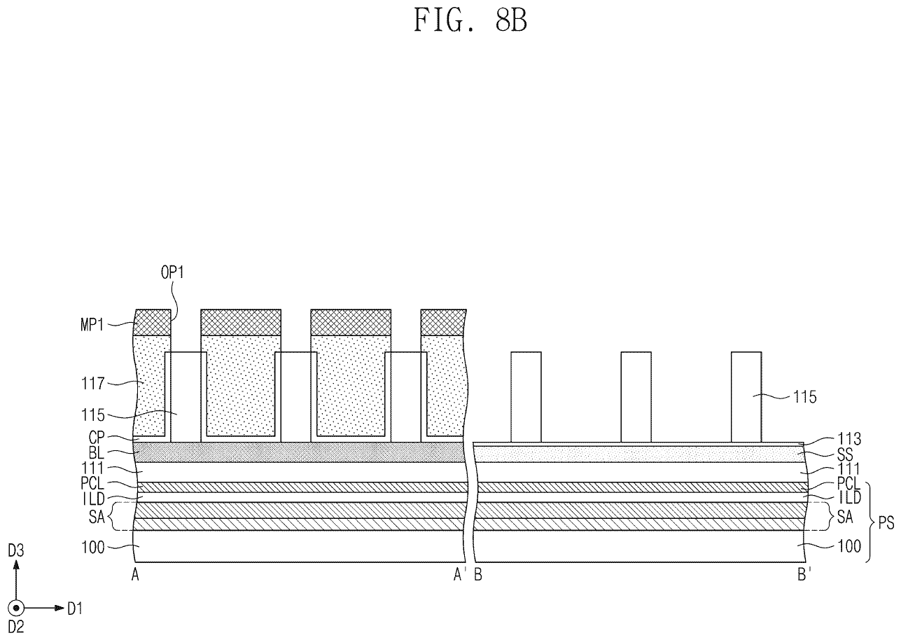

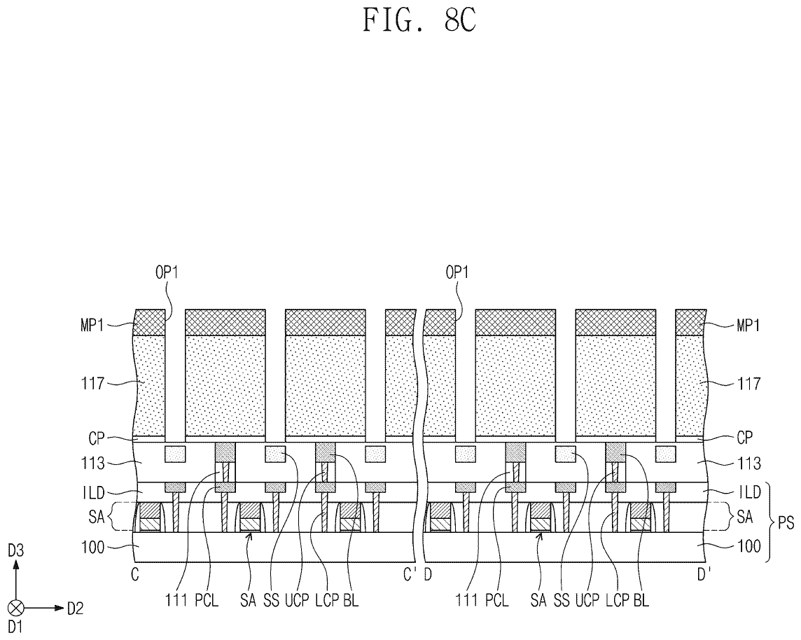

In FIGS. 8A, 8B, and 8C, a second interlayer dielectric pattern 113 may be formed on the lower dielectric layer ILD. The formation of the second interlayer dielectric pattern 113 may include depositing a dielectric material on the second interlayer dielectric layer 113a and the shield structures SS, and performing a planarization process on the dielectric material and the second interlayer dielectric layer 113a. The planarization process may expose top surfaces of the bit lines BL. The planarization process may not expose top surfaces of the shield structures SS.

After that, mold dielectric patterns 115 may be formed on the second interlayer dielectric pattern 113 and the bit lines BL. The mold dielectric patterns 115 may extend in a second direction D2, and may be spaced apart from each other in the first direction D1. The mold dielectric patterns 115 may expose portions of the bit lines BL.

The mold dielectric patterns 115 may include a material having an etch selectivity with respect to the second interlayer dielectric pattern 113. For example, the mold dielectric patterns 115 may include one or more of silicon oxide, silicon nitride, silicon oxynitride, and low-k dielectric materials.

A channel layer may be formed to cover the mold dielectric patterns 115. The channel layer may be formed to have a uniform thickness. The channel layer may be in contact with the second interlayer dielectric pattern 113 and portions of the bit lines BL. The channel layer may be formed by using at least one selected from physical vapor deposition (PVD), thermal chemical deposition process (thermal CVD), low pressure chemical vapor deposition (LPCVD), plasma enhanced chemical vapor deposition (PECVD), and atomic layer deposition (ALD). For example, the channel layer may include a semiconductor material, an oxide semiconductor material, or a two-dimensional semiconductor material, and may include silicon, germanium, silicon-germanium, or indium gallium zinc oxide (IGZO).

A sacrificial layer 117 may be formed on the channel layer. The sacrificial layer 117 may have a substantially flat top surface. The sacrificial layer 117 may include a material having an etch selectivity with respect to the mold dielectric patterns 115. For example, the sacrificial layer 117 may include one of dielectric materials and silicon oxides that are formed by using spin-on-glass (SOG) technology.

Next, a first mask pattern MP1 may be formed on the sacrificial layer 117. The first mask pattern MP1 may have first openings OP1. The first openings OP1 of the first mask pattern MP1 may be spaced apart from each other in the first direction D1 and the second direction D2. After the formation of the first mask pattern MP1, an etching process may be performed which uses the first mask pattern MP1. The etching process may remove a portion of the channel layer and the sacrificial layer 117, and may expose portions of the mold dielectric patterns 115 and the second interlayer dielectric pattern 113. The partial removal of the channel layer, such that the channel layer may be formed into channel patterns CP.

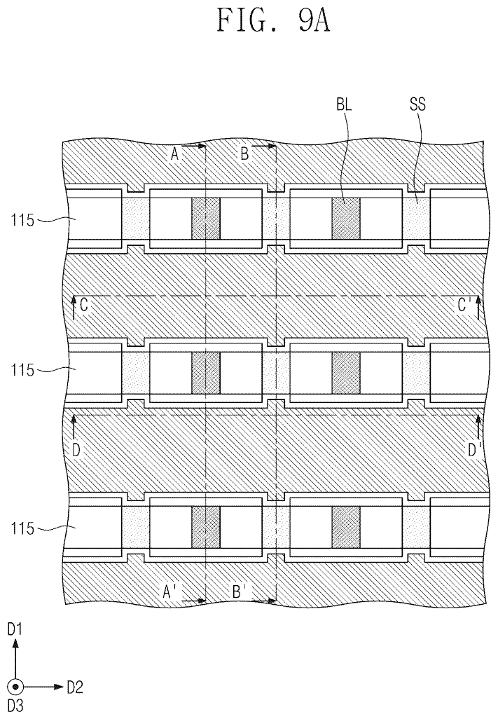

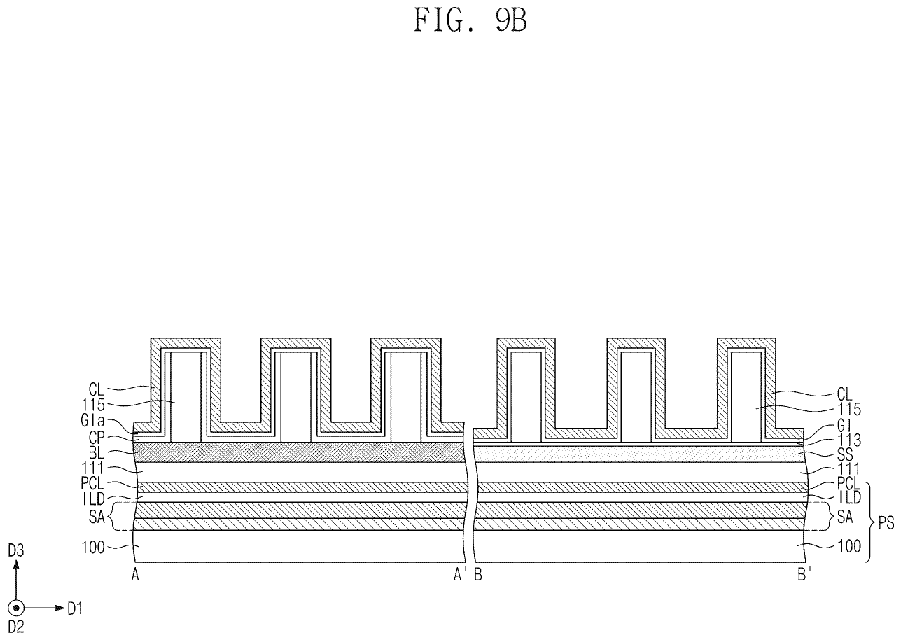

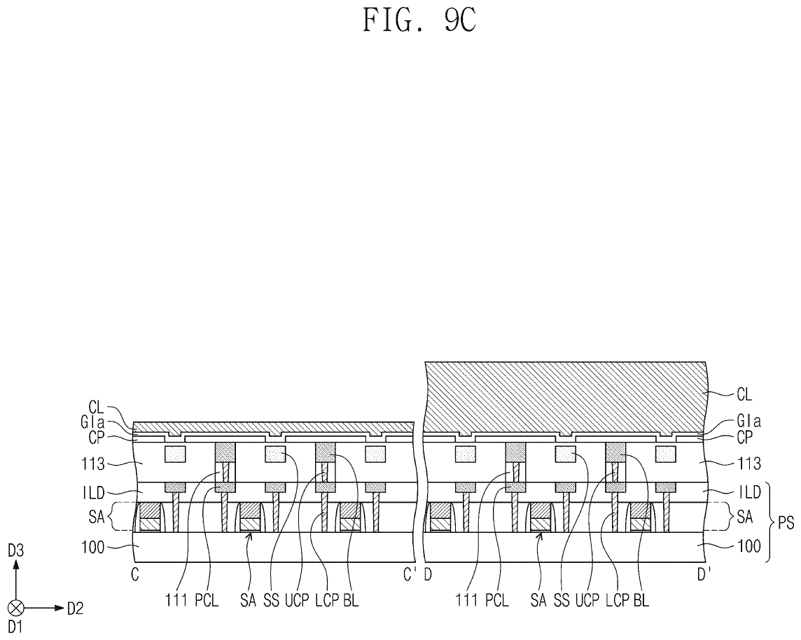

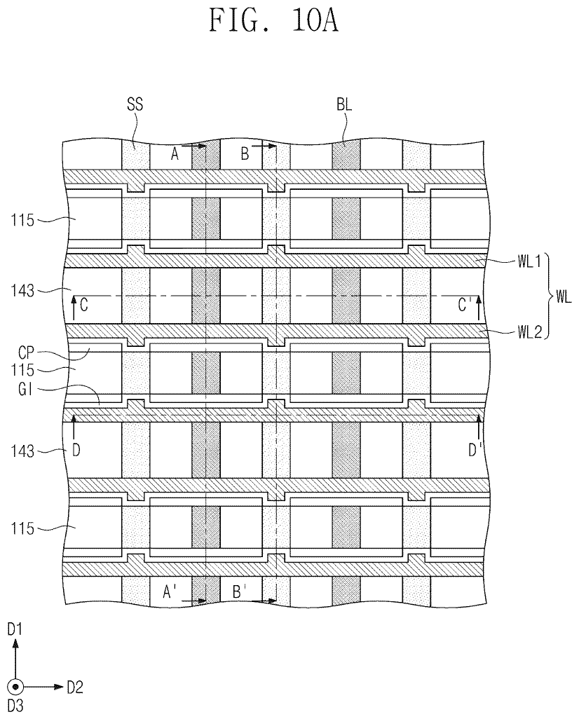

In FIGS. 9A, 9B, and 9C, after the formation of the channel patterns CP, the first mask pattern MP1 and the sacrificial layer 117 may be removed. The sacrificial layer 117 may be removed by using an etching process that has an etch selectivity with respect to the mold dielectric patterns 115 and the channel patterns CP. Accordingly, the channel patterns CP may be exposed.

A preliminary gate dielectric layer GIa and a gate conductive layer CL may be sequentially formed on the channel patterns CP. The preliminary gate dielectric layer GIa may have a uniform thickness that covers the channel patterns CP and the mold dielectric patterns 115. The gate conductive layer CL may have a uniform thickness that covers the preliminary gate dielectric layer GIa. The thickness of the gate conductive layer CL may be substantially greater than that of the preliminary gate dielectric layer GIa. The preliminary gate dielectric layer GIa and the gate conductive layer CL may be formed by using at least one selected from physical vapor deposition (PVD), thermal chemical deposition process (thermal CVD), low pressure chemical vapor deposition (LPCVD), plasma enhanced chemical vapor deposition (PECVD), and atomic layer deposition (ALD).

After the formation of the gate conductive layer CL, a spacer layer may be formed on the gate conductive layer CL, but the present disclosure is not limited thereto.

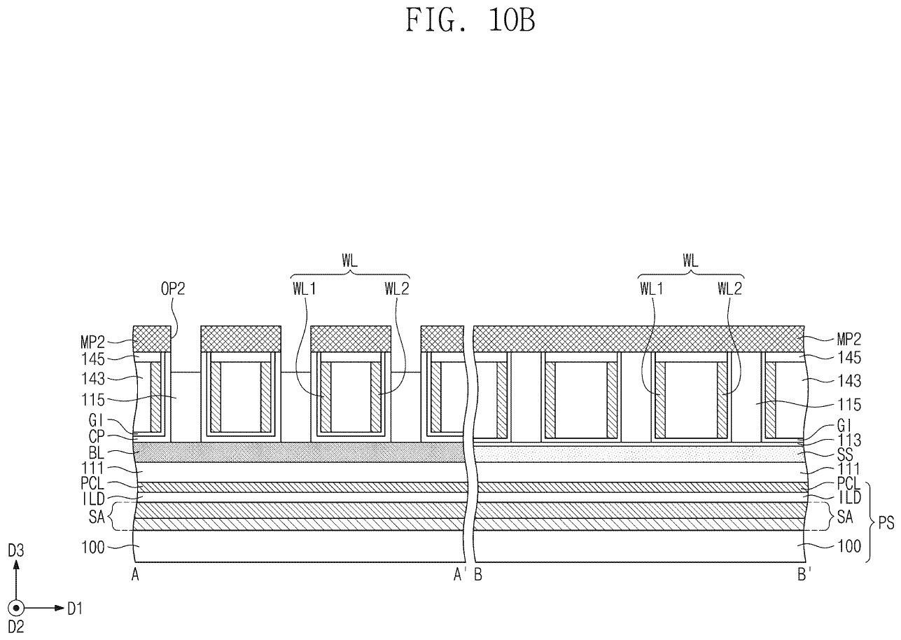

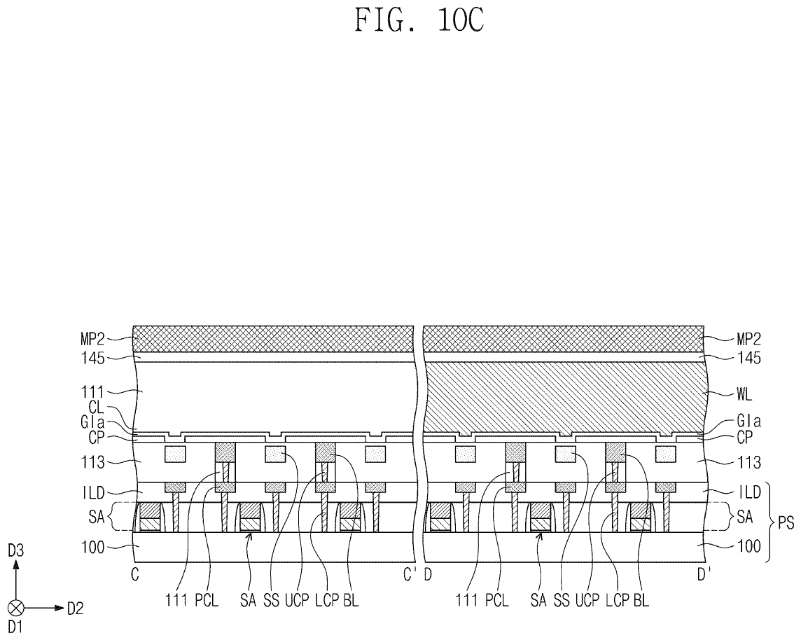

In FIGS. 10A, 10B, and 10C, first and second word lines WL1 and WL2 may be formed. The gate conductive layer CL may undergo an anisotropic etching process to form the first and second word lines WL1 and WL2. The anisotropic etching process may cause the first and second word lines WL1 and WL2 to have their top surfaces lower than those of the channel patterns CP.

Afterwards, first dielectric patterns 143 may be formed between a pair of first and second word lines WL1 and WL2. Each of the first dielectric patterns 143 may fill a space between a pair of first and second word lines WL1 and WL2. The first dielectric patterns 143 may have their top surfaces coplanar with those of the first and second word lines WL1 and WL2.

Capping patterns 145 may be formed on the first dielectric patterns 143. The formation of the capping patterns 145 may include performing a planarization process to expose top surfaces top surfaces of the mold dielectric patterns 115. The capping patterns 145 may have their top surfaces coplanar with those of the channel patterns CP and those of the mold dielectric patterns 115.

After the formation of the capping patterns 145, a second mask pattern MP2 may be formed on the capping patterns 145 and the mold dielectric patterns 115. The second mask pattern MP2 may have second openings OP2. The second openings OP2 may be spaced apart from each other in the first direction D1, and may expose portions of the mold dielectric patterns 115. After the formation of the second mask pattern MP2, an etching process may be performed which uses the second mask pattern MP2. Upper portions of some of the mold dielectric patterns 115 exposed by the etching process may be removed to expose portions of sidewalls of the channel patterns CP. For example, top surfaces of some of the mold dielectric patterns 115 may be lower than top surfaces of a remainder of the mold dielectric patterns 115.

According to some implementations, an etching process using the second mask pattern MP2 may remove portions of the channel patterns CP. For example, as discussed with reference to FIG. 4B, the vertical parts VP1 and VP2 of each of the channel patterns CP may have their recesses RS.

According to some implementations, an etching process using the second mask pattern MP2 may have a difference in etch rate between the channel patterns CP and the mold dielectric patterns 115. For example, as discussed with reference to FIG. 4C, the vertical parts VP1 and VP2 of each of the channel patterns CP may have their inclined sidewalls.

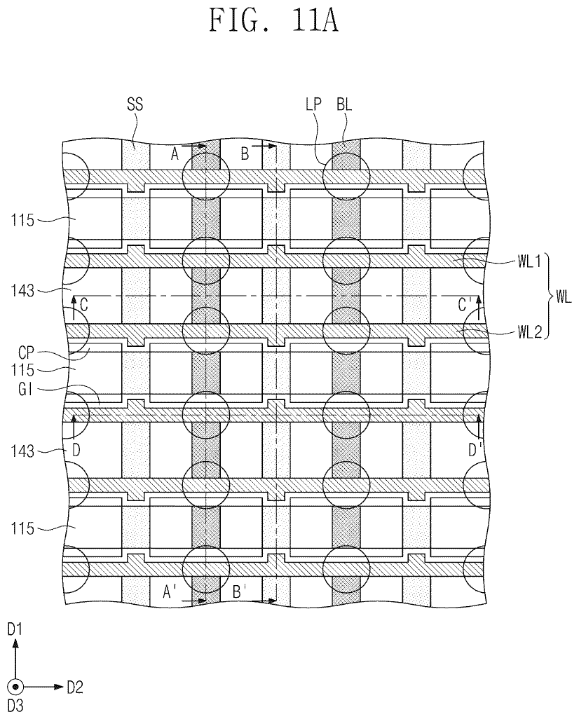

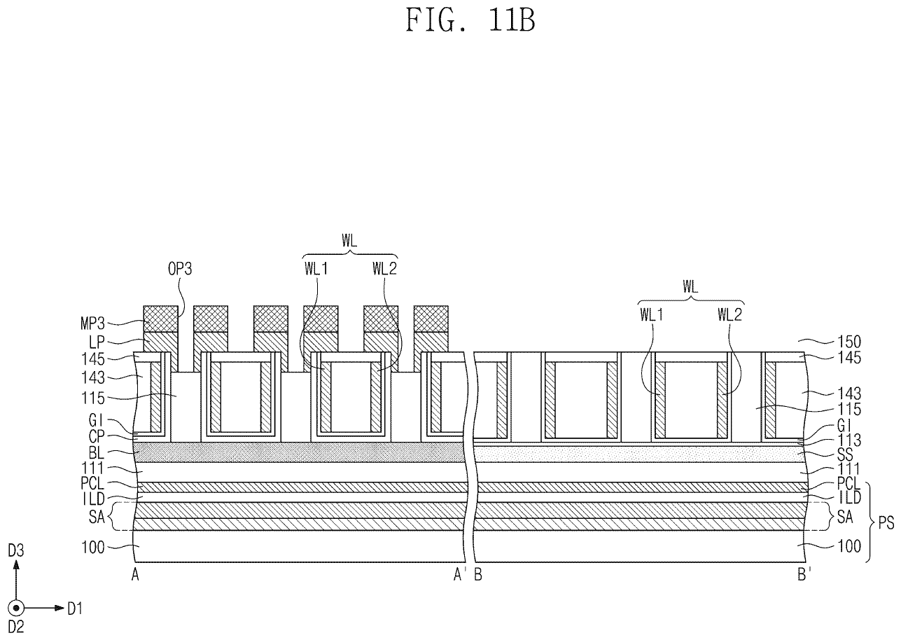

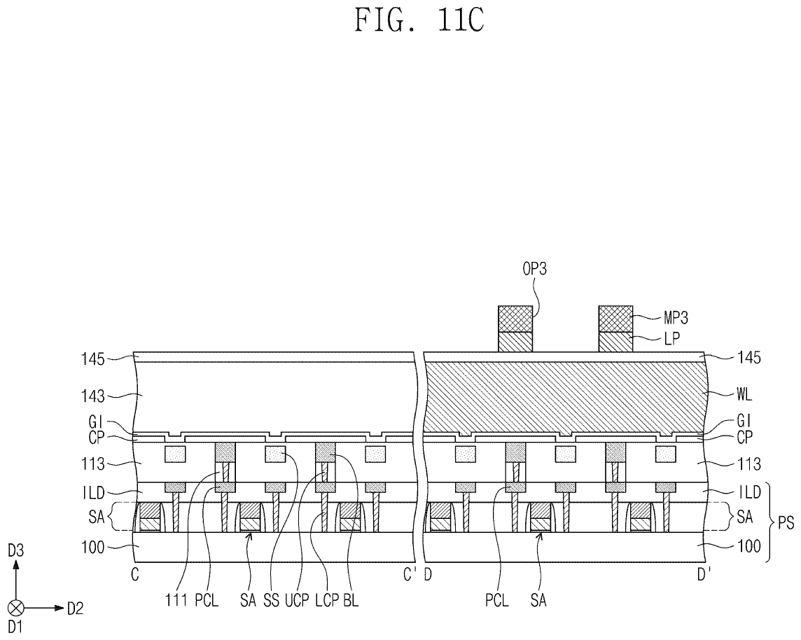

In FIGS. 11A, 11B, and 11C, after the removal of the second mask pattern MP2, an upper conductive layer may be formed on a front surface of the semiconductor substrate 100. The upper conductive layer may cover the top surfaces of the capping patterns 145 and the top surfaces of the mold dielectric patterns 115. In addition, the upper conductive layer may cover portions of the sidewalls of the channel patterns CP. For example, the upper conductive layer may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or any combination thereof.

A third mask pattern MP3 may be formed on the upper conductive layer. The third mask pattern MP3 may have third openings OP3. The third openings OP3 may be spaced apart from each other in the first direction D1 and the second direction D2. Each of the third openings OP3 may have a circular shape when viewed in plan, but the present inventive concepts are not limited thereto. After the formation of the third mask pattern MP3, an etching process may be performed which uses the third mask pattern MP3. The etching process may remove a portion of the upper conductive layer, and may expose portions of the mold dielectric patterns 115 and the capping patterns 145. Accordingly, landing pads LP may be formed which are spaced apart from each other in the first direction D1 and the second direction D2.

In FIGS. 3A, 3B, and 3C, second dielectric patterns 150 may be formed on the capping patterns 145 and between the landing pads LP. The formation of the second dielectric patterns 150 may include forming a second dielectric layer to cover the landing pads LP and the capping patterns 145, and allowing the second dielectric layer to undergo a planarization process to expose top surfaces of the landing pads LP.

After the formation of the second dielectric patterns 150, data storage patterns DSP may be correspondingly formed on the landing pads LP. When the data storage patterns DSP include capacitors, bottom electrodes, a capacitor dielectric layer, and a top electrode may be sequentially formed. The bottom electrodes may be connected to corresponding landing pads LP.

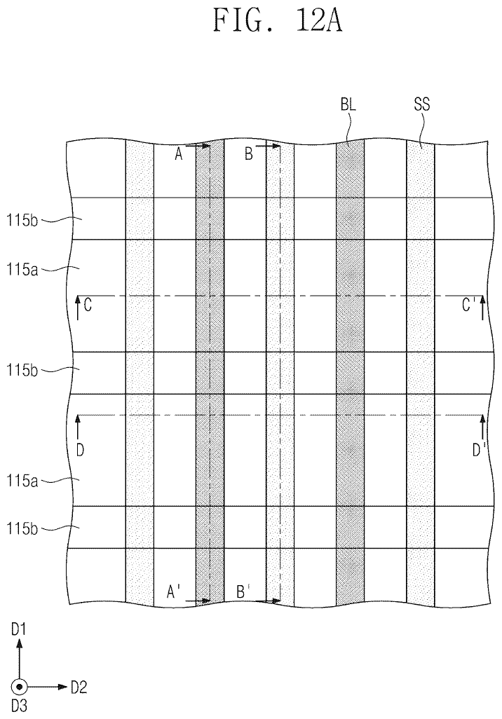

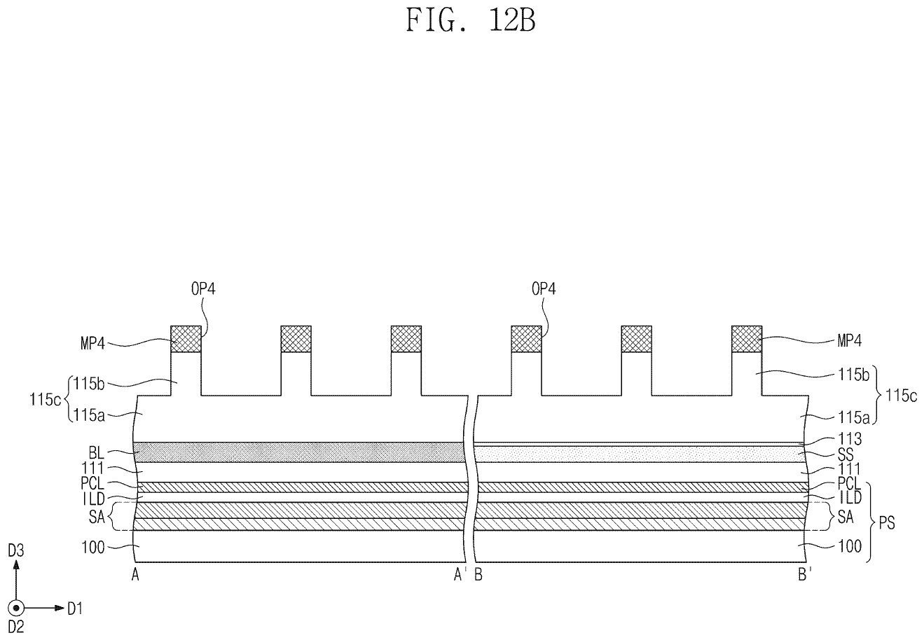

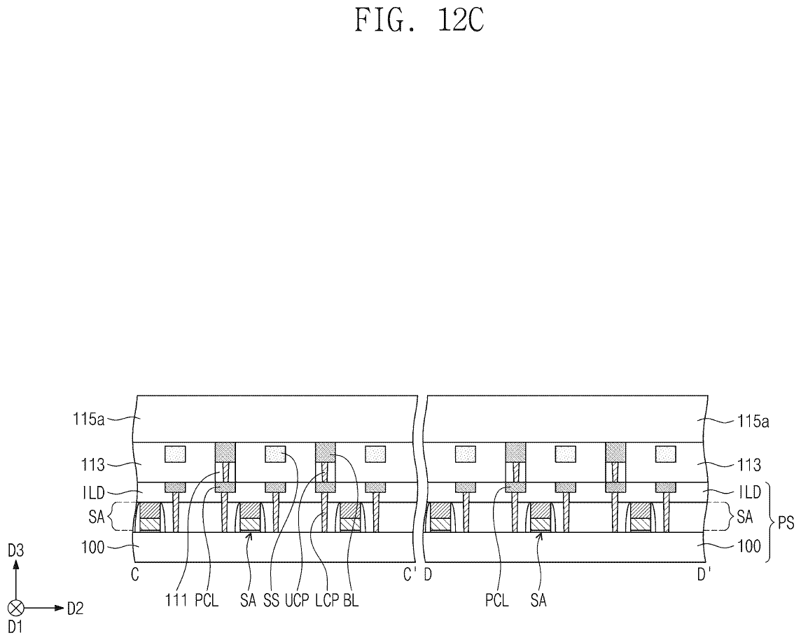

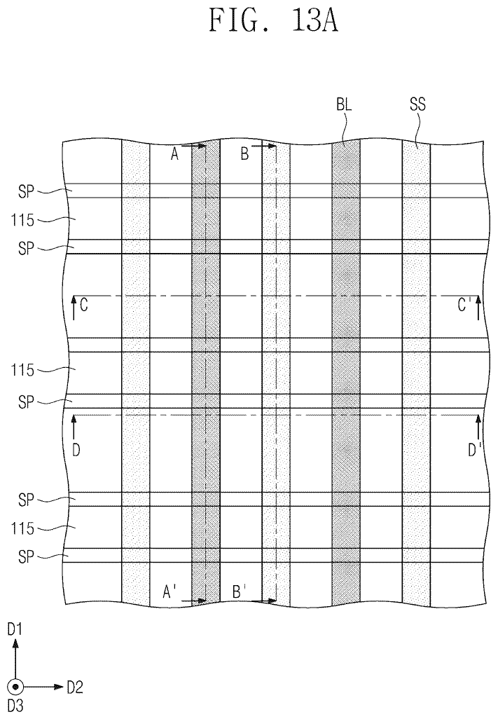

FIGS. 12A to 14C illustrate diagrams showing an example of a method of fabricating a semiconductor memory device according to some implementations. FIGS. 12A, 13A, and 14A illustrate plan views showing an example of a semiconductor memory device according to some implementations. FIGS. 12B, 12C, 13B, 13C, 14B, and 14C illustrate cross-sectional views taken along lines A-A′, B-B′, C-C′, and D-D′ of FIGS. 12A, 13A, and 14A according to some implementations.

In FIGS. 12A, 12B, and 12C, a peripheral circuit structure PS including core circuits SA may be formed on a semiconductor substrate 100. The formation of the peripheral circuit structure Ps may be substantially the same as that discussed with reference to FIGS. 6A, 6B, and 6C.

First and second interlayer dielectric patterns 111 and 113 may be formed on the peripheral circuit structure PS, and bit lines BL and shield structures SS may be formed in the second interlayer dielectric pattern 113. The formation of the first and second interlayer dielectric patterns 111 and 113, the bit lines BL, and the shield structures SS may be substantially the same as that discussed with reference to FIGS. 7A, 7B, and 7C.

A preliminary mold dielectric pattern 115c may be formed on the second interlayer dielectric pattern 113 and the bit lines BL. The preliminary mold dielectric pattern 115c may include a lower part 115a and upper parts 115b. The lower part 115a of the preliminary mold dielectric pattern 115c may cover top surfaces of the bit lines BL and a top surface of the second interlayer dielectric pattern 113. The upper parts 115b of the preliminary mold dielectric pattern 115c may be positioned on the lower part 115a of the preliminary mold dielectric pattern 115c. The upper parts 115b of the preliminary mold dielectric pattern 115c may extend in the second direction D2 and may be spaced apart from each other in the first direction D1.

The formation of the preliminary mold dielectric pattern 115c may include forming on a mold dielectric layer a fourth mask pattern MP4 having fourth openings OP4, performing an etching process using the fourth mask pattern MP4 to remove a portion of the mold dielectric layer, and forming the preliminary mold dielectric pattern 115c including the lower part 115a and the upper parts 115b.

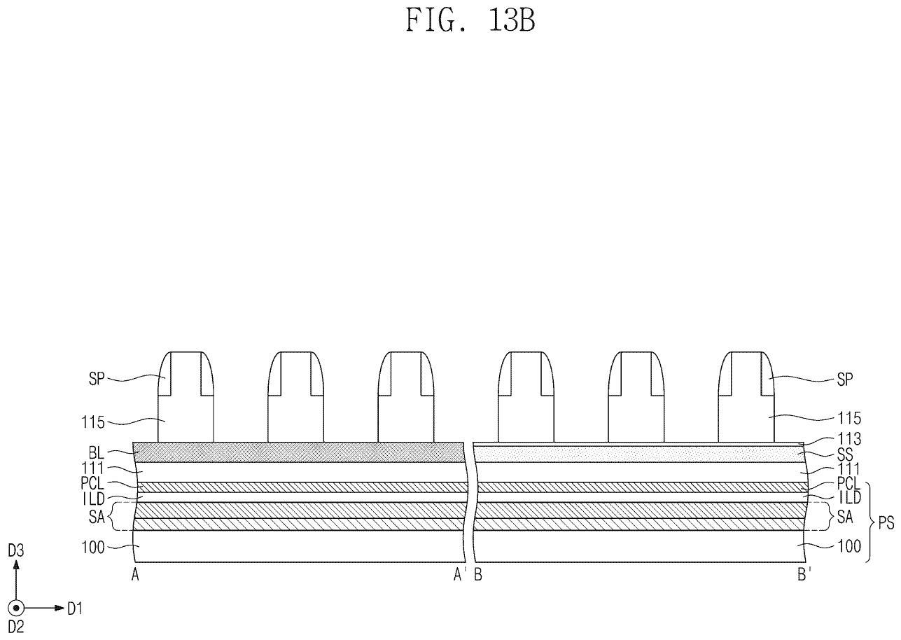

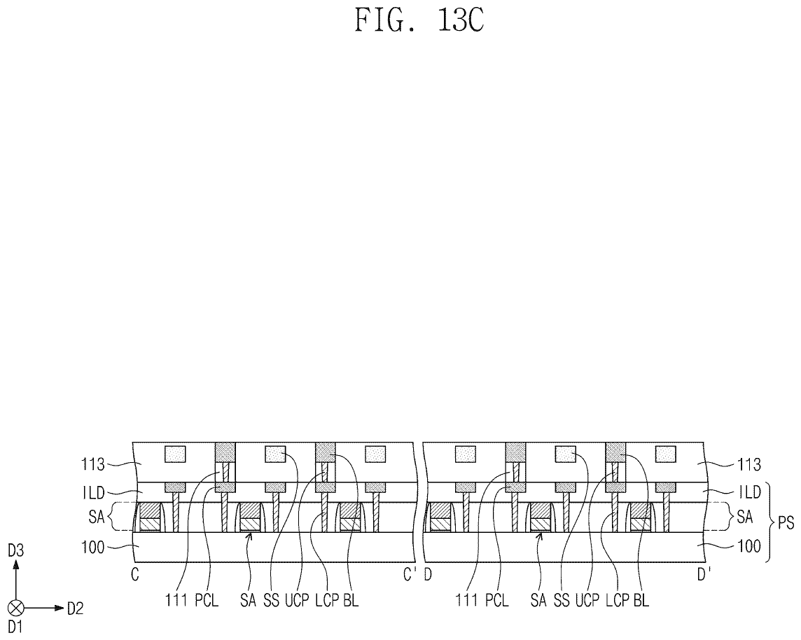

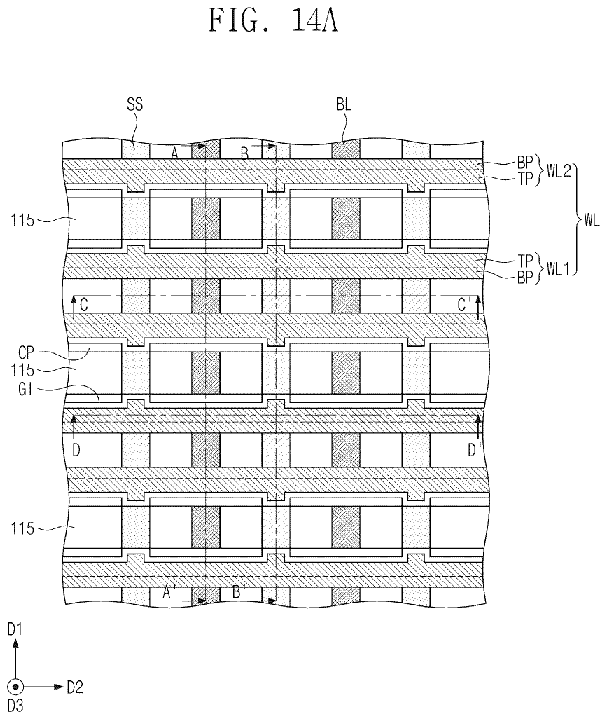

In FIGS. 13A, 13B, and 13C, mold dielectric patterns 115 may be formed, and spacers SP may be formed on the mold dielectric patterns 115. The formation of the mold dielectric patterns 115 and the spacers SP may include forming on the preliminary mold dielectric pattern 115c a spacer layer having a uniform thickness, performing an etching process on the spacer layer, and removing the fourth mask pattern MP4.

An etching process may remove a portion of the preliminary mold dielectric pattern 115c and a portion of the spacer layer, and may expose portions of the bit lines BL and a portion of the second interlayer dielectric pattern 113. Accordingly, the mold dielectric patterns 115 may be formed spaced apart from each other in the first direction D1, and the spacers SP may be formed on the mold dielectric patterns 115.

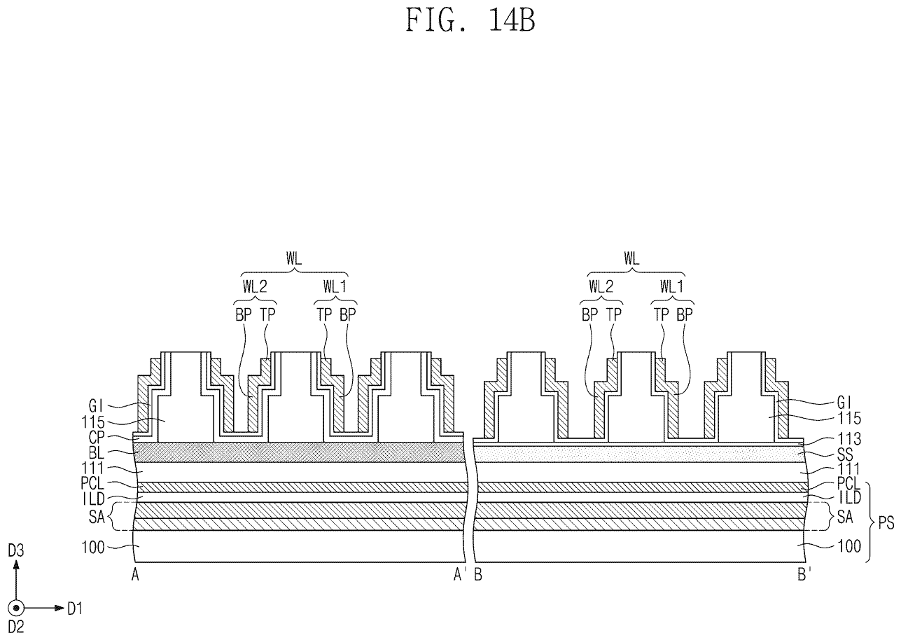

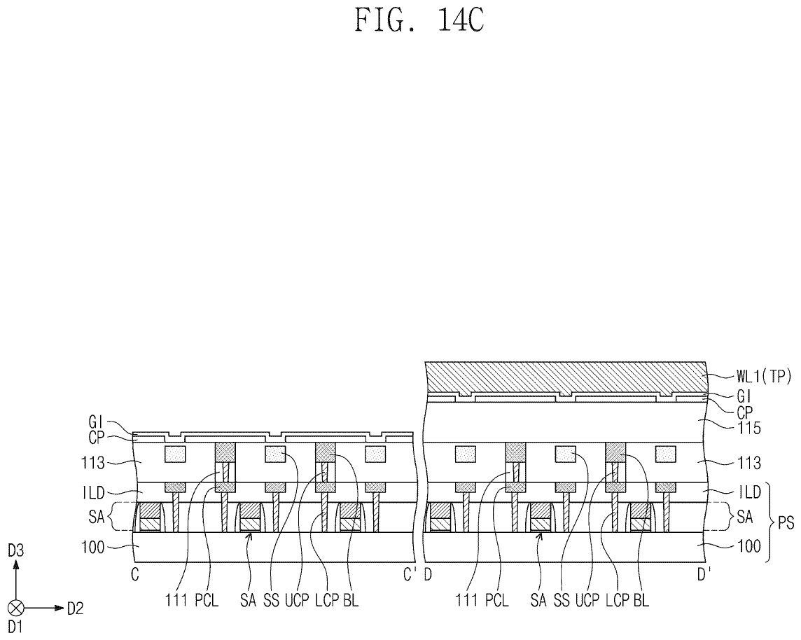

In FIGS. 14A, 14B, and 14C, the spacers SP on the mold dielectric patterns 115 may be removed, and channel patterns CP, a gate dielectric layer GI, and word lines WL may be sequentially formed. The formation of the channel patterns CP, the gate dielectric layer GI, and the word lines WL may be substantially the same as that discussed with reference to FIGS. 8A to 10C.

The channel patterns CP may be formed to have a uniform thickness between the mold dielectric patterns 115 and on the second interlayer dielectric pattern 113. The gate dielectric layer GI may have a uniform thickness to cover the channel patterns CP. The word lines WL may include first and second word lines WL1 and WL2, and each of the first and second word lines WL1 and WL2 may include an upper part TP and a bottom part BP that are shifted from each other in the first direction D1. For example, the first and second word lines WL1 and WL2 may be substantially the same as that discussed with reference to FIG. 5A.

A landing pad of a semiconductor memory device according to some implementations may be in partial contact with a sidewall of a vertical part of a channel pattern, and may be in contact with a top surface of the vertical part of the channel pattern. In some implementations, the landing pad may be in contact with an inclined sidewall of the vertical part of the channel pattern. Accordingly, a contact area between the channel pattern and the landing pad may be increased to reduce a contact resistance between the channel pattern and the landing pad. Accordingly, the semiconductor memory device may improve in electrical properties.

A landing pad of a semiconductor memory device according to some implementations may include a first part on a sidewall of a vertical part of a channel pattern, and may also include a second part on the first part. The first part and the second part may include different materials from each other, and a contact resistance between the first part and the channel pattern may be less than that between the second part and the channel pattern. Accordingly, there may be a reduction in contact resistance between the channel pattern and the landing pad. Accordingly, the semiconductor memory device may improve in electrical properties.

In a semiconductor memory device according to some implementations, a distance between word lines may be different at top and bottom parts between the word lines. In addition, the word lines may have their sidewalls each of which has a step difference. Accordingly, there may be an increase in length of a channel pattern for the word lines. Accordingly, the semiconductor memory device may improve in electrical properties.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor memory device, comprising:
a bit line on a semiconductor substrate, the bit line extending in a first direction;
a channel pattern on the bit line, the channel pattern including a horizontal part and a vertical part connected to an end of the horizontal part;
a word line on the channel pattern, the word line extending in a second direction that intersects the first direction; and
a landing pad on the channel pattern,
wherein the landing pad includes:
a first part in contact with a portion of a sidewall of the vertical part of the channel pattern; and
a second part on the first part, and
wherein the vertical part extends in a third direction that intersects the first direction and the second direction.

2. The device of claim 1, wherein the second part of the landing pad contacts a top surface of the vertical part.

3. The device of claim 1, wherein the vertical part of the channel pattern has a recess at an upper portion of the vertical part,
wherein the first part of the landing pad is provided at the recess of the vertical part.

4. The device of claim 1, wherein the portion of the sidewall of the vertical part of the channel pattern is inclined relative to the third direction.

5. The device of claim 1, wherein the first part and the second part of the landing pad include different materials from each other.

6. The device of claim 1, wherein a top surface of the first part of the landing pad is higher than a top surface of the vertical part of the channel pattern.

7. The device of claim 1, wherein the second part of the landing pad is spaced apart from the channel pattern.

8. The device of claim 1, wherein the channel pattern includes an oxide semiconductor.

9. The device of claim 1, wherein the vertical part of the channel pattern extends onto a top surface of the word line.

10. The device of claim 9, further comprising a gate dielectric layer between the channel pattern and the word line,
wherein the gate dielectric layer contacts the top surface of the word line.

11. The device of claim 1, further comprising a data storage pattern on the landing pad,
wherein the data storage pattern is electrically connected through the landing pad to the channel pattern.

12. A semiconductor memory device, comprising:
a bit line on a semiconductor substrate, the bit line extending in a first direction;
a channel pattern on the bit line, the channel pattern including a horizontal part, a first vertical part, and a second vertical part, the first vertical part and the second vertical part being connected to opposite ends of the horizontal part;
a first word line and a second word line on the horizontal part between the first vertical part and the second vertical part; and
a plurality of landing pads, each on the first vertical part and the second vertical part,
wherein each of the first word line and the second word line includes:
a bottom part adjacent to the bit line; and
a top part adjacent to the plurality of landing pads,
wherein a distance between the first word line and the second word line is different at the bottom part and the top part.

13. The device of claim 12, wherein each of the plurality of landing pads includes:
a first part in contact with portions of sidewalls of the first vertical part and the second vertical part; and
a second part on top surfaces of the first vertical part and the second vertical part.

14. The device of claim 13,
wherein the bottom part of each of the first word line and the second word line extends onto the horizontal part of the channel pattern, and
wherein the top part of each of the first word line and the second word line extends along the first vertical part and the second vertical part of the channel pattern.

15. The device of claim 13,
wherein the first part and the second part of each of the plurality of landing pads include different materials from each other,
wherein the second part is spaced apart from the first vertical part and the second vertical part.

16. The device of claim 12,
wherein the bottom part and the top part of each of the first word line and the second word line are connected to each other, and
wherein the bottom part and the top part are shifted from each other in the first direction.

17. A semiconductor memory device, comprising:
a peripheral circuit structure that includes a plurality of peripheral circuits on a semiconductor substrate and a lower dielectric layer covering the plurality of peripheral circuits;
a plurality of bit lines that extend in a first direction on the peripheral circuit structure;
a plurality of word lines that extend in a second direction on the bit lines, the second direction intersecting the first direction;
a plurality of channel patterns between the bit lines and the word lines;
a gate dielectric layer between the word lines and the channel patterns;
a plurality of data storage patterns on the channel patterns; and
a plurality of landing pads between the plurality of channel patterns and the data storage patterns,
wherein each of the plurality of channel patterns includes:
a horizontal part; and
a plurality of vertical parts that extend in a third direction from the horizontal part, the third direction intersecting the first and second directions, and
wherein each of the plurality of landing pads includes:
a first part in contact with portions of sidewalls of the vertical parts; and
a second part on the first part.

18. The device of claim 17,
wherein each of the word lines includes a bottom part and a top part on the bottom part, and
wherein a distance between the word lines is different at the bottom part and the top part.

19. The device of claim 17, wherein the second part of each of the plurality of landing pads contacts top surfaces of the vertical parts of the channel pattern.

20. The device of claim 17,
wherein the first part and the second part of each of the plurality of landing pads include different materials from each other, and
wherein the plurality of channel patterns include indium-gallium-zinc oxide.
